(19) United States
(12) Patent Application Publication
(10) Pub. No.: US 2024/0355690 A1
(43) Pub. Date: Oct. 24, 2024

(54) A SILICONE COMPOSITION IN THE POTTING OF ELECTRONIC COMPONENTS

(71) Applicant: Momentive Performance Materials Inc., Waterford, NY (US)

(72) Inventors: Andrea RUPPENTHAL, Leverkusen (DE); Matthias GROSSMANN, Haibach (DE); Umesh MISTRY, Manchester (GB); Karen WILKEN, Odenthal (DE)

(21) Appl. No.: 18/580,324

(22) PCT Filed: Jul. 19, 2022
(86) PCT No.: PCT/US2022/037594

§ 371 Date: Jan. 18, 2024

Related U.S. Application Data
(60) Provisional application No. 63/223,290, filed on Jul. 19, 2021.

(51) Int. Cl. H01L 23/29; C08J 3/24; C08K 5/56; C08L 83/06

(52) U.S. Cl. CPC H01L 23/296; C08J 3/246; C08K 5/56; C08L 83/06; C08L 2203/206; C08L 2205/025; C08L 2314/08

(57) ABSTRACT

Provided is a composition that exhibits curing characteristics and can be cured by exposure to high energy conditions (i.e., photo-activatable) and optionally by exposure to non-photoactivatable conditions (e.g., condensation curing and/or at elevated temperatures). The present compositions are suitable for use as a potting compound in electronic applications and can be used as a material to fill space in and around electronic components. The compositions also display excellent adhesion to a variety of substrates. Also provided are methods of curing and using the compositions in various applications.

### FIELD

The present invention relates to a silicone composition both photocurable and non-photocurable, containing polysiloxane with unsaturated hydrocarbon groups bound to silicon atoms and polysiloxane with hydrogen bound to a silicon atom which belong to addition cure systems in the potting/encapsulation of electronic components, particularly in automotive and power applications for the protection against moisture, dust and environmental hazards.

The present invention also relates to a new silicone composition and a process for photoactivatable and/or non-photoactivatable curing of the curable silicone composition.

The field of application of such crosslinkable silicone compositions is that of raw materials used in the electronics sector. A similar application to coatings of electronic components is that of the encapsulation of such components according to the technique known as “potting”. A potting material is typically used for sealing of connectors and electronic devices to ensure tightness of the system and electrical insulation under automotive requirements. This avoids the contamination of the electronic devices due to moisture, water, dust and environmental or corrosive agents.

### BACKGROUND

Potting materials need to be applied as a flowable liquid in a pocket of the connector and cured rapidly via an UV radiation-process to ensure fast handling after potting application. Main curing process must be possible only with UV activation without additional temperature process, but for shadow areas (places in the chamber/cavity not accessible to light or radiation) a second curing mechanism is required. The material must be temperature stable (up to 80° C.) already after UV activation.

The products generally used in this application are silicone gels, which have the function of protecting the sensitive components and which must have damping, shock, vibrational and thermal stress protection on fragile electronic components and dielectric properties. In these applications, the silicone compositions have turned out to be the materials of choice given their resistance to temperatures, their stability to UV radiation, their flexibility at low temperature and their insulating capacity (high dielectric strength).

The silicone compositions crosslinkable in two ways have more particularly imposed themselves because of the flexibility and the speed of implementation specific to photocrosslinking under UV radiation supplemented by crosslinking by hydrolysis/condensation at atmospheric humidity at room temperature, or heating, which makes it possible to overcome the inefficiency of the photocrosslinking in the zones not exposed to the radiation (shadow zones). Thus, a brief exposure to UV makes it possible to harden and make non-tacky the protective coatings prepared from said compositions crosslinkable in two ways

Some commercially available potting silicones include one component compositions such as U.S. Pat. No. 4,271,425 which are cured by moisture, requiring from several hours to days to complete the cure. Faster cures may be obtained from two component systems such as those in U.S. Pat. No. 4,087,585 if elevated temperatures are provided. The two-component systems which require a platinum catalyst, however, are inhibited by organotin compounds, sulfur, amines, urethanes and unsaturated hydrocarbon plasticizers on the substrate surfaces.

Most systems crosslinkable in two ways are based on UV curing and curing under moisture, leading to undesired by-products for the applications. Some systems crosslinkable in two ways contain acrylate based product needing a radical polymerization, not being the best choice for the application.

WO2019088066 describes a hydrosilylable composition that can provide, during curing of same, a half-cured product which is stable; and a half-cured product and a cured product which are obtained using the hydrosilylable composition and which is also referring to the use of a one component system for pressure sensitive adhesive application which is not adequate for the potting application as the silicone composition should have enough pot life to allow its application according to the present invention.

### SUMMARY

The following presents a summary of this disclosure to provide a basic understanding of some aspects. This summary is intended to neither identify key or critical elements nor define any limitations of embodiments or claims. Furthermore, this summary may provide a simplified overview of some aspects that may be described in greater detail in other portions of this disclosure.

Accordingly, it is desirable to use a silicone composition provided as a first part and a second part which will produce an elastomeric or soft gel consistency upon curing without the formation of by-products and avoiding radical polymerization for the potting of electronic components like PCB (printed circuit board) assemblies as well as switches and electronic connectors with pins having areas not accessible to photocurable curing. The silicone composition should be flowable enough to allow the correct filling into the electronic component with areas non accessible to photocuring. Furthermore, it is desirable that the composition be capable of curing by a further curing mechanism in areas of the curing cavity/chamber/mold which are not readily accessible to photocuring. Still further, when used on low energy substrates such as thermoplastics, the composition should display adequate adhesion over the substrate.

These technical problems are not adequately addressed and/or solved by the state of the art.

In accordance with one aspect of the present invention there is provided a potting compound comprising a curable silicone composition, the composition comprising:
(A) at least one polyorganosiloxane having at least one, preferably at least two alkenyl group bonded to a silicon atom,
(B) at least one organohydrogensiloxane having at least one SiH group,
(C1) at least one photo-activatable hydrosilylation catalyst,
(C2) at least one non-photo-activatable hydrosilylation catalyst, and
(D) optionally additives,
for potting and encapsulation of electronic components, more specifically in automotive and power applications for the protection against moisture, dust and environmental hazards.

In one embodiment, the composition is provided as a first part and a second part with a first part comprising the at least one organopolysiloxane having at least one alkenyl group, the photo-activatable catalyst, and the non-photo-activatable catalyst and a second part comprising the at least one organohydrogensiloxane. In one aspect, the compositions are cured by exposing the composition (after application to a desired location, e.g., cavity, mold, chamber, etc.) to UV irradiation to cure the composition in areas accessible to such irradiation, and subsequently exposing the composition to a temperature sufficient to cure the composition in areas that are not accessible to UV irradiation.

In one aspect, provided are articles comprising the cured compositions.

In one aspect, provided is a potting compound for use in the potting of electronic equipment, the potting compound comprising a curable silicone composition the composition comprising:
(A) at least one polyorganosiloxane having at least one alkenyl groups bonded to a silicon atom,
(B) at least one organohydrogensiloxane having at least one SiH group,
(C1) at least one photo-activatable hydrosilylation catalyst,
(C2) at least one non-photo-activatable hydrosilylation catalyst, and
(D) optionally additives.

In one embodiment, the electronic components are for automotive or power applications. In one embodiment, the protection of an electronic equipment against moisture, dust, and/or environmental hazards.

In one embodiment in accordance with any of the previous embodiments, the at least one polyorganosiloxane having at least one alkenyl group A) is selected from the groups of polyorganosiloxanes having the formula (Ia):

[MₐD_{b}T_{c}Q_{d}R⁹ₑ]ₘ (Ia)

wherein the indices in formula (Ia) are defined as follows:
a=0-10
b=0-2000
c=0-50
d=0-1
e=0-300
m=1-1000
with a, b, c, d and m being such that the viscosity of component (A) at 20° C. is less than 15000 mPa·s(measured at a shear rate of D=10 s⁻¹ according to DIN 53019 and for viscosities below 5000 mPa·s measured according to DIN 53015),
and
M is selected from R₃SiO_{1/2} and M*,
D is selected from R₂SiO_{2/2} and D*,
T is selected from RSiO_{3/2} and T*, and
Q=SiO_{4/2},
R⁹ is selected from divalent organic groups bound via carbon to two silicon atoms, and wherein each R, which may be the same or different, is selected from an optionally substituted alkyl group with up to 30 carbon atoms, an optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation, and
wherein M*=R¹ₚR₃₋ₚSiO_{1/2}, D*=R¹_{q}R_{2-q}SiO_{2/2}, T*=R¹SiO_{3/2},
wherein
p=1-3
q=1-2
R is as defined before, and
R¹ is selected from alkenyl groups.

In one embodiment in accordance with any of the previous embodiments, the component (A) has the formula (Ia1)

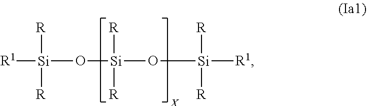

wherein R¹ and R are as defined above and x is ≥0.

In one embodiment in accordance with any of the previous embodiments, the component (B) is selected from the group of (B1) a linear SiH-containing polyorganosiloxane and (B2) a branched SiH-containing polyorganosiloxane.

In one embodiment in accordance with any of the previous embodiments, the component (B) is selected from the group of (B1) a linear polydiorganosiloxane having an SiH group at each end, and (B2) a branched SiH-containing polyorganosiloxane containing at least one M^{H} unit.

In one embodiment in accordance with any of the previous embodiments, the branched SiH-containing polyorganosiloxane (B2) are selected from polyorganosiloxanes comprising at least one siloxy unit selected from the group consisting of a Q unit:

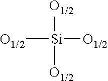

and a T unit:

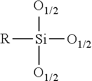

wherein R is as defined above, and at least one siloxy unit M^{H}:

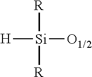

wherein R is alkyl.

In one embodiment in accordance with any of the previous embodiments, the branched SiH-containing polyorganosiloxane B2) are selected from polyorganosiloxanes consisting of at least one siloxy unit Q

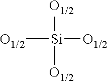

and at least one siloxy unit M^{H}:

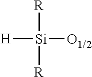

wherein R is as defined above.

In one embodiment in accordance with any of the previous embodiments, the SiH-containing polyorganosiloxane resins (B2) are selected from polyorganohydrogensiloxanes consisting of Q and M^{H} units of the formula

{[Q][M^{H}]_{0.01-00}}ₘ

wherein Q and M^{H} are as defined above, and m is about 1 to about 20.

In one embodiment in accordance with any of the previous embodiments, the potting compound comprises a linear polydiorganosiloxane (B1) having an SiH group at each end, and a branched SiH-containing polyorganosiloxane (B2) consisting of Q and M^{H} units of the formula

{[Q][M^{H}]_{0.01-00}}ₘ

wherein Q, M^{H} and m are as defined above.

In one embodiment in accordance with any of the previous embodiments, the organo-metallic hydrosilylation catalyst (C1) or (C2) is selected from the group consisting of transition metal complex catalysts selected from platinum, palladium, rhodium, nickel, iridium, ruthenium, and iron complexes and combinations thereof.

In one embodiment in accordance with any of the previous embodiments, (C1) is a photo-activatable platinum catalyst selected from the group consisting of η⁵-(optionally substituted)cyclopentadienyl platinum(IV) complexes, β-diketonato trimethylplatinum (IV) complexes, bis(β-diketonato) platinum(II) complexes, bis(phosphine) platinum(II) complexes, cyclooctadiene platinum(II) complexes, and mixtures thereof.

In one embodiment in accordance with any of the previous embodiments, the non-photoactivatable hydrosilylation catalyst (C2) is platinum catalyst selected from the group consisting of platinum compounds such as chloroplatinic acid, or platinum complexes such as platinum/vinylsiloxane complexes, or mixtures thereof.

In one embodiment in accordance with any of the previous embodiments, the potting compound comprises he additive (D) selected from of the group consisting of a hydrosilylation reaction inhibitor.

In one embodiment in accordance with any of the previous embodiments, the potting compound comprises as the additive (D) at least one selected from the group consisting of an optical brightener or UV tracer (fluorescent whitening agent).

In one embodiment in accordance with any of the previous embodiments, the potting compound comprises:
100 parts per weight of at least one polyorganosiloxane (A) having at least one alkenyl group bonded to a silicon atom,
0.1 to 30 parts per weight of at least one organohydrogensiloxane (B) having at least one SiH group,
0.1 to 3.5 weight percent of at least one photo-activatable hydrosilylation catalyst (C1) based on total weight of (A) and (B),
1 to 1000 ppm at least one non-photo-activatable hydrosilylation catalyst (C2) based on the total weight of the components (A) and (B), and
0.1 to 10 parts of optionally additives (D).

In one embodiment in accordance with any of the previous embodiments, the potting compound comprises:
100 parts per weight of at least one polyorganosiloxane (A) having at least one, alkenyl group bonded to a silicon atom,
0.1 to 25 parts per weight of at least one linear polyorganosiloxane (B1) having an SiH group at each end,
0.1 to 5 parts per weight of at least one polyorganohydrogensiloxane (B2) having at least one siloxy unit Q and at least one siloxy unit M^{H} as defined above,
1 to 1000 ppm of at least one photo-activatable hydrosilylation catalyst (C1) based on total weight of (A) and (B),
0.1 to 3.1 weight percent at least one non-photo-activatable hydrosilylation catalyst (C2) based on the total weight of the components (A) and (B), and
0.1 to 10 parts (D) optionally additives.

In one embodiment in accordance with any of the previous embodiments, the said silicone composition has a viscosity below 1000 mPa·s at 20° C. measured according to DIN 53015.

In one embodiment in accordance with any of the previous embodiments:
(A) is selected from at least one linear polyorganosiloxane having at both ends one alkenyl group bonded to a silicon atom,
(B) is selected from a linear polydiorganosiloxane (B1) having an SiH group at each end, and an SiH-containing poly organosiloxane resin (B2) consisting of Q and M^{H} units as defined above,
(C1) at least one photo-activatable hydrosilylation catalyst,
(C2) at least one non-photo-activatable hydrosilylation catalyst, and

In one embodiment in accordance with any of the previous embodiments, the potting compound comprises at least one adhesion enhancing agent (E).

In one embodiment in accordance with any of the previous embodiments, the adhesion agent is selected from a titanate compound.

In one embodiment in accordance with any of the previous embodiments, the adhesion enhancing agent (E) is tetra-n butyltitanate.

In one embodiment in accordance with any of the previous embodiments, the said silicone composition has a viscosity below 1000 mPa·s at 20° C. measured according to DIN 53015.

In another aspect, provided is a process of curing the curable silicone composition as defined in any of the previous embodiments to a cured silicone composition in a chamber/cavity of the electronic component having areas not readily accessible to direct UV light irradiation, the process comprising:
a) applying the said curable silicone composition into the chamber/cavity in a manner so as to fill in the chamber/cavity.
b) irradiating the chamber/cavity with UV irradiation sufficient to substantially cure the composition in the areas directly accessible to UV light, and
c) exposing the composition on the chamber/cavity to a temperature of >20° C. for sufficient time to cure the composition in the areas not accessible to UV light.

In still another aspect, provided is a process of curing of the curable silicone compositions as defined in any of the previous embodiments to a cured silicone composition for the manufacture of connector potting, the process comprising
a) applying said curable silicone composition to a chamber/cavity/pocket comprising pin connectors,
b) exposing said curable silicone composition to UV light, and
c) then curing in areas not accessible to UV light in a temperature range of 20 to 80° C.

In a further aspect, provided is a cured composition obtained by the curing of the curable silicone composition according to any of the previous embodiments by a UV radiation cure step followed by a cure step at a temperature in the range of ≥20° C. and ≤80° C.

In yet another aspect, provided is an article prepared by the steps, comprising:
I. mixing, so as to form a curable composition as defined in any of the previous embodiments,
II. applying a potting of/dispensing said curable composition into a chamber/cavity of the electronic component; and
III. curing said curable composition to said chamber/cavity by exposing the said curable composition in the potting chamber/cavity to a source of UV radiation and thereafter non photoactivatable curing said curable composition at a temperature in the range of 20 to 80° C.

In one embodiment, the substrate is a circuit board or pin connector.

In yet a further aspect, provided is a use of the curable silicone composition, as defined in any of the preceding claims in the form of a kit of two parts system.

In another aspect, provided is a composition comprising:
(a) a first part comprising (A) at least one polyorganosiloxane having at least one alkenyl group bonded to a silicon atom, (C1) at least one photo-activatable hydrosilylation catalyst, and (C2) at least one non-photo-activatable hydrosilylation catalyst, and
(b) a second part comprising (B) at least one organohydrogensiloxane having at least one SiH group, and (D1) a polyorganosiloxane, different from (B) comprising at least one unit selected from the group consisting of
R(H)SiO_{2/2} and
R⁵(R)SiO_{2/2},
wherein R is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation, R⁵ is selected from the group consisting of unsaturated aliphatic group with up to 14 carbon atoms, epoxy-group-containing aliphatic group with up to 14 carbon atoms, cyanurate-containing group, and an isocyanurate-containing group, and further comprising at least one unit of the formula (3):

—O_{2/2}(R)Si—R⁴—SiR_{d}(OR³)_{3-d} (3)

wherein
R in formula (3) may be identical or different and is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation,
R³ is selected from H (hydrogen) and alkyl radicals having 1 to 6 carbon atoms, and may be identical or different,
R⁴ is a difunctional optionally substituted hydrocarbyl radical with up to 15 carbon atoms, which may contain one or more heteroatoms selected from O, N and S atoms, and which is bond to the silicon atoms via an Si—C-bond, and
d is 0 to 2.

In one embodiment, the polyorganosiloxane (A) is selected from at least one linear polyorganosiloxane having at least one alkenyl group; and the organohydrogensiloxane (B) is selected from at least one linear polydiorganosiloxane (B1) having an SiH group at each end, and at least one SiH-containing polyorganosiloxane resin (B2) consisting of Q and M^{H} units where Q is SiO_{4/2}, and M^{H} is HR₂SiO_{1/2}, where R of the M^{H} unit may be identical or different and is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4) alkyleneoxy groups, the groups R being free of aliphatic unsaturation.

In one embodiment in accordance with any of the previous embodiments, the composition comprises:
100 parts per weight of the at least one polyorganosiloxane (A) having at least one alkenyl group bonded to a silicon atom,
0.1 to 25 parts per weight of the at least one linear polyorganosiloxane (B1) having an SiH group at each end,
0.1 to 5 parts per weight of the at least one polyorganohydrogensiloxane (B2) having at least one siloxy unit Q and at least one siloxy unit M^{H} as defined above,
1 to 1000 ppm of the at least one photo-activatable hydrosilylation catalyst (C1) based on total weight of (A) and (B),
0.1 to 3.1 weight percent at least one non-photo-activatable hydrosilylation catalyst (C2) based on the total weight of the components (A) and (B),
0.1 to 10 weight percent of the component (D1) based on the total weight of part (a) and (b), and
0.001 to 10 parts per weight of an additive.

In one embodiment in accordance with any of the previous embodiments, (D1) is selected from a compound of the formula (3a):

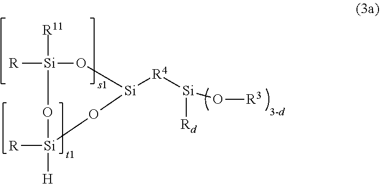

R¹¹ is R or R⁵; and R⁴ is a difunctional optionally substituted hydrocarbyl radical with up to 15 carbon atoms, which may contain one or more heteroatoms selected from O, N and S atoms, and which is bond to the silicon atoms via an Si—C-bond,
s1=0-6
t1=0-6
s1+t1=2-6
with the proviso that there is at least one group —(OSi(R)H)— or —(OSi(R)(R¹¹)— in the compound.

In one embodiment in accordance with any of the previous embodiments, the compound of formula (3a) has the formula:

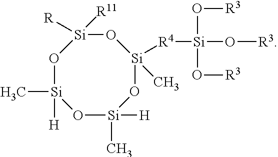

In one embodiment in accordance with any of the previous embodiments, the compound of formula (3a) has the formula:

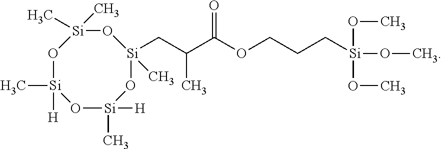 [SMILES: CO[Si](CCCOC(=O)C(C)C[Si]1(C)O[SiH](C)O[SiH](C)O[Si](C)(C)O1)(OC)OC]

In one embodiment in accordance with any of the previous embodiments, the polyorganosiloxane (A) is of the formula (Jal):

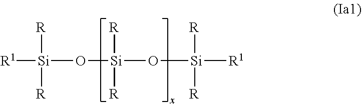

wherein each R is independently selected from a saturated organic group, each R¹ is independently selected from an alkenyl group, and x is ≥0.

In one embodiment in accordance with any of the previous embodiments, the composition, upon combining parts (a) and (b), has a viscosity of from about 50 mPa·s to about 10 Pa·s at 20° C. measured at a shear rate of D=10 s⁻¹ according to DIN 53019 for viscosities above 5000 mPa·s and measured according to DIN 53015 at 20° C. for viscosities below 5000 mPa·s.

In one embodiment in accordance with any of the previous embodiments, the composition, upon combining parts (a) and (b), has a viscosity of 100 mPa·s to about 1000 mPa·s at 20° C. measured according to DIN 53015.

In one embodiment in accordance with any of the previous embodiments, the composition, upon combining parts (a) and (b), has a viscosity of 200 mPa·s to about 800 mPa·s at 20° C. measured according to DIN 53015.

In one embodiment in accordance with any of the previous embodiments, the composition, upon combining parts (a) and (b), has a viscosity of 300 mPa·s to about 500 mPa·s at 20° C. measured according to DIN 53015.

In one embodiment in accordance with any of the previous embodiments, the silicone composition has a viscosity below 1000 mPa·s at 20° C. measured according to DIN 53015.

In one aspect, provide is a process of curing the curable silicone composition as defined in any of the previous embodiments in a chamber/cavity of an electronic component having areas not readily accessible to direct UV light irradiation, the process comprising:
(i) combining part (a) and part (b) to form the curable silicone composition;
(ii) applying the curable silicone composition into the chamber/cavity in a manner so as to fill in the chamber/cavity;
(iii) irradiating the chamber/cavity with UV irradiation sufficient to substantially cure the composition in the areas directly accessible to UV light; and
(iv) exposing the composition on the chamber/cavity to a temperature of ≥20° C. for sufficient time to cure the composition in the areas not accessible to UV light.

In another aspect, provided is a process of curing the curable silicone compositions as defined in any of the previous embodiments to a cured silicone composition for the manufacture of connector potting or encapsulation of electronic components, the process comprising
(i) combining part (a) and part (b) to form the curable composition;
(ii) applying said curable silicone composition to a chamber/cavity/pocket comprising pin connectors,
(iii) exposing said curable silicone composition to UV light, and
(iv) curing in areas not accessible to UV light in a temperature range of 20 to 80° C.

In a further aspect, provided is an article prepared by:
(i) mixing part (a) and part (b), so as to form a curable composition as defined in any of the previous embodiments,
(ii) applying a potting of/dispensing of said curable composition into a chamber/cavity of the electronic component; and
(iii) curing said curable composition to said chamber/cavity by exposing the said curable composition in potting chamber/cavity to a source of UV radiation and thereafter non-photoactivatable curing said curable composition at a temperature in the range of 20 to 80° C.

In one embodiment, the substrate is a circuit board or a connector plug.

In still another aspect, provided is a composition comprising:
(A) at least one polyorganosiloxane having at least one, alkenyl groups bonded to a silicon atom.
(B) at least one organohydrogensiloxane having at least one SiH group,
(C1) at least one photo-activatable hydrosilylation catalyst,
(C2) at least one non-photo-activatable hydrosilylation catalyst, and
(D1) A polyorganosiloxane comprising at least one unit selected from the group consisting of
R(H)SiO_{2/2} and
R⁵(R)SiO_{2/2},
wherein R is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation, R⁵ is selected from the group consisting of unsaturated aliphatic group with up to 14 carbon atoms, epoxy-group-containing aliphatic group with up to 14 carbon atoms, cyanurate-containing group, and an isocyanurate-containing group, and
further comprising at least one unit of the formula (3):

—O_{2/2}(R)Si—R⁴—SiR_{d}(OR³)_{3-d} (3)

wherein
R in formula (3) may be identical or different and is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation,
R³ is selected from H (hydrogen) and alkyl radicals having 1 to 6 carbon atoms, and may be identical or different,
R⁴ is a difunctional optionally substituted hydrocarbyl radical with up to 15 carbon atoms, which may contain one or more heteroatoms selected from O, N and S atoms, and which is bond to the silicon atoms via an Si—C-bond, and
d is 0 to 2.

In one embodiment, the composition comprises an adhesion enhancing agent (E).

In one embodiment in accordance with any of the previous embodiments, the composition has a lap shear strength of at least 0.1 MPa when interposed between a first substrate that is glass and a second substrate that is either Aluminium or PBT.

In one embodiment in accordance with any of the previous embodiments, the composition has a cohesive failure in the range of 60-100% in the cured state on a metal or plastic substrate in a OverLapShear (OLS) Test.

In one embodiment in accordance with any of the previous embodiments, the composition has a cohesive failure in the range of 60-100% in the cured state on an aluminium or PBT substrate in a OverLapShear (OLS) Test.

In a further aspect, provided is a use of a curable silicone composition of any of the previous embodiments as a potting compound in the potting of electronic components. In one embodiment, the electronic components are for automotive or power applications.

In one embodiment, the electronic components are for automotive or power applications.

In one embodiment, the use is for the protection against moisture, dust, and/or environmental hazards.

These and other aspects and embodiments are further understood with respect to the following detailed description.

### DETAILED DESCRIPTION

Reference will now be made to exemplary embodiments. It is to be understood that other embodiments may be utilized and structural and functional changes may be made. Moreover, features of the various embodiments may be combined or altered. As such, the following description is presented by way of illustration only and should not limit in any way the various alternatives and modifications that may be made to the illustrated embodiments. In this disclosure, numerous specific details provide a thorough understanding of the subject disclosure. It should be understood that aspects of this disclosure may be practiced with other embodiments not necessarily including all aspects described herein, etc.

As used herein, the words “example” and “exemplary” means an instance, or illustration. The words “example” or “exemplary” do not indicate a key or preferred aspect or embodiment. The word “or” is intended to be inclusive rather than exclusive, unless context suggests otherwise. As an example, the phrase “A employs B or C,” includes any inclusive permutation (e.g., A employs B; A employs C; or A employs both B and C). As another matter, the articles “a” and “an” are generally intended to mean and may be used interchangeably with the phrases “one or more,” “at least one,” and the like unless context suggest otherwise. The word “adhesion enhancing agent” means a substance that increases adhesion between two surfaces, typically between the surface of a silicone composition and the surface of a substrate.

Numerical values presented in a range or subsets of ranges can be combined to form new and non-specified ranges.

Provided is a composition that exhibits curing characteristics and can be cured by exposure to high energy conditions (i.e., photo-activatable) as well as by exposure to non-photoactivatable conditions (e.g., condensation curing and/or at elevated temperatures). The present compositions are suitable for use as a potting compound in electronic applications and can be used as a material to fill space in and around electronic components. Also provided are methods of curing and using the compositions in various applications.

Unless stated otherwise viscosities above 5000 mPa·s mentioned herein are determined in accordance with DIN 53019 and, in general, they are measured at a shear rate of D=10 s⁻¹ at 20° C. For the viscosities below 5000 mPa·s, h eviscosities are measured usig the falling ball viscosimenter according to Höppler method and DIN 53015.

The present composition comprises: (A) at least one polyorganosiloxane having at least one, preferably at least two, alkenyl group bonded to a silicon atom,
(B) at least one organohydrogensiloxane having at least one SiH group,
(C1) at least one photo-activatable hydrosilylation catalyst,
(C2) at least one non-photo-activatable hydrosilylation catalyst, and
(D) optionally an additive.

### Component (A)

The curable silicone composition used according to the invention comprises at least one polydiorganosiloxane (A), having at least one, preferably at least two, alkenyl groups bonded to a silicon atom. In the context of the invention the alkenyl group is, in particular, an optionally substituted hydrocarbyl that contains a carbon-carbon double bond, which is reactive in the hydrosilylation reaction. It does not include any kinds of acrylate groups (having a carbonyl group adjacent to the carbon-carbon double bond:

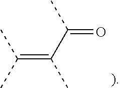

The alkenyl groups are selected from e.g., from linear, branched, or cyclic alkenyl groups, such as C₂-C₂₀ alkenyl, C₆-C₃₀-cycloalkenyl, C₈-C₃₀-alkenylaryl, cycloalkenylalkyl, vinyl, allyl, methallyl, 3-butenyl, 5-hexenyl, 7-octenyl, ethyliden-norbornyl, styryl, vinylphenylethyl, norbornenyl-ethyl, limo-nenyl, which optionally can comprise one or more O- or F-atoms. Preferred alkenyl groups are vinyl, allyl, methallyl, 3-butenyl, 5-hexenyl, more preferred groups are vinyl groups. Preferred components (A) can be described by the general formula (Ia),

[MₐD_{b}T_{c}Q_{d}R⁹ₑ]ₘ (Ia)

wherein the indices in formula (Ia) represent the molar ratios of the siloxy units M, D, T and Q, which can be distributed blockwise or randomly in the polysiloxane. Within a polysiloxane each siloxane unit M, D, and T can be identical or different, and
a=0-10
b=0-2000
c=0-50
d=0-1
e=0-300
m=1-1000
with a, b, c, d and m being such that the viscosity of component (A) at 20° C. is less than 15000 mPa·s, preferably 10000 mPa·s, more preferably less than 5000 mPa·s and still more preferably less than 1000 mPa·s (measured at a shear rate of D=10 s⁻¹ according to DIN 53019 for viscosities above 5000 mPa·s and for viscosities below 5000 mPa·s with a falling ball viscosimeter according to Höppler and DIN 53015).

The viscosity of component (A) refers to the viscosity of a single component (A) or a mixture of components (A). The latter case of the mixture includes with it the presence of individual components (A1) that may have a viscosity exceeding 15000 mPa·s at 20° C., for example resinous components (A1) that comprise Q and/or T units.

In the formula (Ia):
M=R₃SiO_{1/2}, or M*
D=R₂SiO_{2/2}, or D*
T=RSiO_{3/2}, or T*
Q=SiO_{4/2},
divalent R⁹, which are bridging groups between the siloxy groups above,
wherein each R, which may be the same or different, is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation, and
wherein M*=R¹ₚR₃₋ₚSiO_{1/2}, D*=R¹_{q}R_{2-q}SiO_{2/2}, T*=R¹SiO_{3/2},
wherein
p=1-3, preferably 1,
q=1-2, and
R¹ is preferably selected from unsaturated groups, comprising C═C-group-containing groups (alkenyl groups), e.g.: n-alkenyl, iso-alkenyl, tertiary-alkenyl, or cyclic alkenyl, C₆-C₃₀-cycloalkenyl, C₈-C₃₀-alkenylaryl, cycloalkenylalkyl, vinyl, allyl, methallyl, 3-butenyl, 5-hexenyl, 7-octenyl, ethyliden-norbornyl, styryl, vinylphenylethyl, norbornenyl-ethyl, limo-nenyl, optionally substituted by one or more O- or F-atoms.
R⁹ is selected from divalent organic groups bound via carbon to two silicon atoms, preferably as defined below.

In one embodiment, R is preferably selected from n-, iso-, or tertiary-alkyl, alkoxyalkyl, C₅-C₃₀-cyclic alkyl, or C₆-C₃₀-aryl, alkylaryl, which groups can be substituted in addition by one or more O-, N-, S- or F-atom, or poly(C₂-C₄)-alkylene ethers with up to 500 alkylene oxy units the groups R being free of aliphatic unsaturation.

Examples of suitable monovalent hydrocarbon radicals include alkyl radicals, preferably such as CH₃—, CH₃CH₂—, (CH₃)₂CH—, C₈H₁₇— and C₁₀H₂₁—, and cycloaliphatic radicals, such as cyclohexylethyl, aryl radicals, such as phenyl, tolyl, xylyl, aralkyl radicals, such as benzyl and 2-phenylethyl. Preferable monovalent halohydrocarbon radicals have the formula CₙF₂ₙ₊₁CH₂CH₂— wherein n has a value of from 1 to 10, such as, for example, CF₃CH₂CH₂—, C₄F₉CH₂CH₂—, C₆F₁₃CH₂CH₂—, C₂F₅—O(CF₂—CF₂—O)_{1- 10}CF₂—, F[CF(CF₃)—CF₂—O]₁₋₅—(CF₂)₀₋₂—, C₃F₇—OCF(CF₃)— and C₃F₇—OCF(CF₃)—CF₂—OCF(CF₃)—. Exemplary groups for R include, but are not limited to, methyl, phenyl, and 3,3,3-trifluoropropyl.

In one embodiment, the alkenyl radicals (R¹) are preferable attached to terminal silicon atoms, the olefin function is at the end of the alkenyl group of the higher alkenyl radicals, because of the more ready availability of the alpha-, omega-dienes used to prepare the alkenylsiloxanes.

Preferred groups for R¹ are vinyl, 5-hexenyl, cyclohexenyl, limonyl, styryl, vinylphenylethyl.

The R⁹ group forms bridging elements between two siloxy units. R⁹ includes for example divalent aliphatic or aromatic n-, iso-, tertiary- or cyclo-alkylene with up to 14 carbon atoms, arylene or alkylenearyl groups.

In embodiments, the content of the R⁹ groups does not exceed 30 mol. % preferably not exceed 20 mol. % of all siloxy units. Preferably R⁹ is absent.

Preferred examples of suitable divalent hydrocarbon groups R⁹ include any alkylene residue, preferably such as —CH₂—, —CH₂CH₂—, —CH₂(CH₃)CH—, —(CH₂)₄—, —CH₂CH(CH₃)CH₂—, —(CH₂)₆—, —(CH₂)₈— and —(CH₂)₁₈—; cycloalkylene radical, such as cyclohexylene; arylene radicals, such as phenylene, xylene and combinations of hydrocarbon radicals, such as benzylene, i.e. —CH₂CH₂—C₆H₄—CH₂CH₂—, —C₆H₄CH₂—. Preferred groups are alpha, omega-ethylene, alpha, omega-hexylene, or 1,4-phenylene.

Further examples include divalent halohydrocarbon radicals R⁹, e.g., any divalent hydrocarbon group R⁹ wherein one or more hydrogen atoms have been replaced by halogen, such as fluorine, chlorine or bromine. Preferable divalent halohydrocarbon residues have the formula —CH₂CH₂(CF₂)₁₋₁₀CH₂CH₂— such as for example, —CH₂CH₂CF₂CF₂CH₂CH₂— or other examples of suitable divalent hydrocarbon ether radicals and halohydrocarbon ether radicals including —CH₂CH₂OCH₂CH₂—, —C₆H₄—O—C₆H₄—, —CH₂CH₂CF₂OCF₂CH₂CH₂—, and —CH₂CH₂OCH₂CH₂CH₂—.

In embodiments, (M*+T*+D*) is at least two and can be greater than 2.

According to another embodiment of the silicone composition according to the invention the component A) is preferably at least one polydiorganosiloxane of the formula (Ia1),

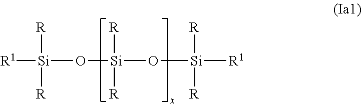

wherein each R is as defined above, and R¹ is independently selected from alkenyl groups preferably as defined above, and x is ≥0.

In one embodiment of the current invention, the variable x, which was introduced with regards to the structure (Ia1) above and corresponds to the variable “b”, is 10 to 2000, preferably 20 to 1500, more preferably 25 to 1000 and even more preferably 30 to 500. These ranges are meant to comprise both end-points each. The variable x is an average value calculated from the number-average molecular weight Mₙ of the polydiorganosiloxanes of the formula (Ia1), which is determined by gel permeation chromatography using polystyrene standard or using ¹H NMR.

Further preferred structures of the alkenyl-terminated polydiorganosiloxanes (A) include:

ViMe₂SiO(Me₂SiO)₁₀₋₂₀₀₀ SiMe₂Vi (Ia),

ViPhMeSiO(Me₂SiO)₁₀₋₂₀₀₀SiMePhVi (Ib),

ViMe₂SiO(Me₂SiO)₁₀₋₆₀₀SiMe₂Vi (Ic)

ViMe₂SiO(Me₂SiO)₁₀₋₂₀₀SiMe₂Vi (Id).

wherein Vi is a vinyl group, Me is a methyl group and Ph is a phenyl group. Particularly preferred are polydiorganosiloxanes of formula (Ia), more particularly preferred are the structures of the formula (Ic), most particularly preferred are the structures of the formula (Id) Preferably the alkenyl content of the component (A) is in the range from 0.05 to 0.85 mmol Si-Vinyl per g of molecule (A), more preferably from 0.1 to 0.75 mmol Si-Vinyl per g of molecule (A) and more preferably 0.15 to 0.6 mmol Si-Vinyl per g of molecule (A) (millimoles alkenyl bonded to Si per gram of the entire molecule (A)).

The alkenyl content of the component (A) can be determined here by way of ¹H NMR—see A. L. Smith (ed.): The Analytical Chemistry of Silicones, J. Wiley & Sons 1991 Vol. ¹¹² pp. 356 et seq. in Chemical Analysis ed. by J. D. Winefordner

Furthermore, the use of resinous or branched polyorganosiloxanes of the following formula as component (A) is possible:

{[Q][R¹⁰O_{1/2}]ₙ[M]_{0.01-10}[T]_{0-50, preferably 0}[D]_{0-1000, preferably 0}}ₘ (Ia2)

wherein
Q, T, M, D are as defined above,
n=0 to 3, preferably n=0,
m is as defined above,
R¹⁰ is hydrogen, C₁-C₂₅-alkyl, such as methyl, ethyl, n-propyl, iso-propyl, n-, iso- and tert.-butyl, alkanoyl, such acyl, aryl, —N═CHR, such as butanonoxime, alkenyl, such as propenyl, with the proviso that there is at least one group selected from M*, D* and T*. Most preferred resinous polyorganosiloxanes applied as component (A) are of the formula consisting of Q and M* units,

{[Q][M*]_{0.01-10}[T]_{0-50,preferably 0}[D]_{0-1000, preferably 0}}ₘ (Ia2)

wherein
Q, T, M, D are as defined above,
n=0 to 3, preferably n=0,
m is as defined above,

Most preferred resinous polyorganosiloxanes applied as component (A) are of the formula consisting of Q and M* units,

e.g. {[Q][M*]_{0.01-10, preferably 1-10}}ₘ (Ia3)

wherein Q, M*, and m are as defined above, and m is preferably 1 to 20.

One embodiment of the compounds (Ia3) is provided by way of example by monomeric to polymeric compounds which can be described via the formula [(Me₂R¹SiO_{0.5})ₖSiO_{4/2}]₁₋₁₀₀₀ wherein index k is from 0.3 to 4. Such resinous molecules can contain significant concentrations of SiOH— and/or (C₁-C₆)-alkoxy-Si groups of up to 10 mol. % related to the silicon atoms.

Particular preferred resinous polyorganosiloxanes (A) include, e.g.,
Q(M*)₄,
M₂D₁₀₋₃₀T*_{10-30 or} M₂D*₁₀₋₃₀T₁₀₋₃₀, and
[M*₁₋₄M₀₋₃Q]₁₋₄₀ where M*+M is 4.

In a preferred embodiment, the curable silicone composition used according to the invention does not contain a branched (or resinous) polysiloxane with alkenyl substituent.

Preferred are thus linear polysiloxanes having at least one, preferably at least two alkenyl groups bonded to a silicon atom.

In some cases of potting of pins in connectors, the component (A) more preferably has a viscosity at 20° C. from 15 to 900 mPa·s, preferably from 20 to 600 mPa·s, still more preferably 50 to 500 mPa·s (measured according to DIN 53015).

The component (A) can be used as a single component of one Si-alkenyl-containing polysiloxane or as mixtures of at least two thereof.

In one embodiment, the curable silicone composition comprises at least 50 weight-%, preferably at least 60 weight-%, more preferably at least 65 weight-% of the component (A), based on the total amount of the silicone composition. In one embodiment, the curable silicone composition comprises the component (A) in an amount of from at least 50 weight-% to about 85 weight-%; from about 55 weight-% to about 80 weight-%; from about 60 weight-% to about 75 weight-%; or from about 65 weight-% to about 70 weight-% based on the total amount of the silicone composition.

### Component (B)

The curable silicone composition comprises at least one organohydrogensiloxane having at least one SiH group (component (B)).

In one embodiment, the component (B) is selected from one or more polyorganohydrogensiloxanes of the general formula (IIa):

[M¹ₐ₁D¹_{b1}T¹_{c1}Q¹_{d1}R⁹ₑ₁]ₘ₁ (IIa)

wherein:
M¹=R₃SiO_{1/2}, and/or M**
D¹=R₂SiO_{2/2}, and/or D**
T¹=RSiO_{3/2}, and/or T**
Q¹=SiO_{4/2},
with M**=HR₂SiO_{1/2}, D**=HRSiO_{2/2}, T**=HSiO_{3/2},
R⁹ is as defined above, and
R in formula (IIa) is independently selected from a group as defined above with respect to (Ia),
a1 is 0.01-10, preferably a1 is 2-5, more preferably a1 is 2;
b1 is 0-1000, preferably b1 is 0-500;
c1 is 0-50, preferably c1 is 0;
d1 is 0-5, preferably d1 is 0;
e1 is 0-3, preferably e1 is 0;
m1 is 1-1000, preferably m1 is 1-500, more preferably m1 is 1,
with the proviso that there is at least one group selected from M**, D**, or T**.

Preferably, the component (B) is selected from polyhydrogensiloxanes that have only hydrocarbyl groups, more preferably alkyl and aryl groups, even more preferably only methyl or phenyl groups, and most preferably only methyl groups as organic residues R.

The SiH-content of the polyorganohydrogensiloxanes B) is preferably at least 0.1 mmol/g, more preferably at least 0.2 mmol/g, and at most preferably 17 mmol/g, more preferably at most 15 mmol/g, even more preferably 0.1 to 15 mmol/g, and most preferably 0.2 to 13 mmol/g. If more than one component (B) is used, these Si-contents apply for each specific component B) used.

The range for M¹, D¹, T¹, and Q¹ units present in the molecule can cover nearly all values representing liquid and solid resins. Optionally these siloxanes can comprise additional traces of C₁-C₆-alkoxy or Si-hydroxy groups remaining from the synthesis.

The component (B) can be used as a single component of one SiH-containing polysiloxane or as mixtures of at least two thereof.

In one embodiment according to the invention the used curable silicone composition comprises a component (B) is selected from the group of (B1) a linear SiH-containing polyorganosiloxane and (B2) a branched SiH-containing polyorganosiloxane.

In another embodiment of the current invention the component (B) is selected from (B1) linear polyorganohydrogensiloxanes of formula (IIb) such as

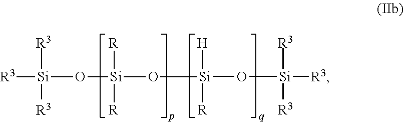

wherein R is as defined above, and R³ is selected from R and H, and p≥0 and q≥0. In formula (IIb) preferably (B1) has one SiH group in the terminal siloxy units and q=0.

The component (B1) preferably has a viscosity at 20° C. from 2 to 2000 mPa·s, preferably from 1 to 1000 mPa·s, still more preferably 2 to 100 mPa·s (measured according to DIN DIN 53015).

In another embodiment according to the invention, the used component (B) is selected from the group of (B1) a linear polydiorganosiloxane having an SiH group at each end, and (B2) a branched SiH-containing polyorganosiloxane containing at least one M** unit. The M**, T**, and D** units may also be referred to herein by the designations M^{H}, T^{H}, and D^{H}, respectively.

In one embodiment, the branched SiH-containing polyorganosiloxane (B2) is selected from polyorganosiloxanes comprising at least one siloxy unit selected from the group consisting of a Q or in this case Q¹ unit:

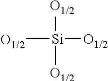

and a T unit:

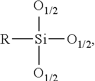

wherein R is as defined above, preferably alkyl with up to 30 carbon atoms, more preferably methyl, (preferably the polyorganosiloxanes resins (B2) comprise at least one Q¹ unit), and and at least one siloxy unit M**:

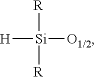

wherein preferably R is alkyl, more preferably methyl.

Preferably the SiH-containing polyorganosiloxanes (B2) are selected from poly organosiloxanes consisting of at least one siloxy unit Q¹:

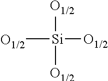

and at least one siloxy unit M**:

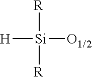

wherein R is as defined above, preferably alkyl with up to 30 carbon atoms, more preferably methyl.

Furthermore, the use of resinous polyorganohydrogensiloxanes of the following formula as component (B2) is possible:

{[Q¹][R¹⁰O_{1/2}]ₙ₁[M¹]_{0.01-10}[T¹]_{10-50, preferably 0}[D¹]_{0-1000, preferably 0}}ₘ₁ (IIc)

wherein
Q¹, T¹, M¹, and D¹ are as defined above,
n1=0 to 3, preferably n1=0,
m1 is as defined above,
R¹⁰ is hydrogen, C₁-C₂₅-alkyl, such as methyl, ethyl, n-propyl, iso-propyl, n-, iso- and tert-butyl, alkanoyl such as acyl, aryl, —N═CHR, such as butanonoxime, alkenyl, such as propenyl,
with the proviso that there is at least one group selected from M**, D** and T**.

Possible example of resinous polydrogensiloxanes are
Q¹(M**)₄, M¹₂D¹₁₀₋₃₀T**₁₀₋₃₀, M¹₂D**₁₀₋₃₀T¹₁₀₋₃₀, and [M**₁₋₄Q¹]₁₋₄₀.

Most preferred resinous polyorganohydrogensiloxanes applied as component (B2) are of the formula consisting of Q¹ and M** units, e.g.

{[Q¹][M**]_{001-10, preferably 1-10}}ₘ₁ (IId)

wherein Q¹, M** and m1 are as defined above, and m1 is preferably 1 to 20, more preferably m1=1.

One preferred embodiment of the compounds (IIc) is provided by way of example by monomeric to polymeric compounds which can be described via the formula [(Me₂HSiO_{0.5})ₖSiO_{4/2}]₁₋₁₀₀₀ wherein index k is from 0.3 to 4. Such resinous molecules can contain significant concentrations of SiOH— and/or (C₁-C₆)-alkoxy-Si groups of up to 10 mol. % related to the silicon atoms.

Particularly preferred resinous polyorganohydrogensiloxanes (B) include e.g.
Q¹(M**)₄, and
[M**₁₋₄Q¹]₁₋₄₀, wherein Q¹ and M** are as defined above

In one embodiment, the component (B) can be used as a mixture of at least one SiH-containing polysiloxane of formula (IIb) and at least one SiH-containing polysiloxane of formula (IId). Preferably the SiH-containing polysiloxanes have groups R being aryl or alkyl, preferably alkyl, more preferably methyl.

In another embodiment, the component (B) can be used as a mixture of at least one SiH-containing polysiloxane of formula (IIb) and at least one SiH-containing polysiloxane of formula (IId) wherein q=0 and only one R³ is a hydrogen at both ends of the SiH-containing polysiloxane. Preferably the SiH-containing polysiloxanes have groups R and the remaining R³ groups being aryl or alkyl, preferably alkyl, more preferably methyl.

### Catalyst Components (C1) and (C2)

The catalyst components (C1) or (C2) for the hydrosilylation reaction of the silicone composition are compounds that catalyze the reaction of the silicon-bonded hydrogen atoms of component (B) with the silicon-bonded alkenyl substituents of component (A). They generally include metal or organo metal compounds selected from the group of Ni, Ir, Rh, Ru, Os, Pd and Pt compounds as taught e.g. in U.S. Pat. Nos. 3,159,601; 3,159,662; 3,419,593; 3,715,334; 3,775,452 and 3,814,730, more preferably they are based on a platinum group metal.

The catalyst can be present on a carrier such as silica gel or powdered charcoal, bearing the metal, or a compound or complex of that metal.

A typical platinum containing catalyst component in the polyorganosiloxane compositions of this invention is any form of platinum (0), (II) or (IV) compounds, which are able to form complexes.

The amount of platinum-containing catalyst component that is used in the compositions of this invention is not narrowly limited as long as there is a sufficient amount to accelerate the hydrosilylation reaction between (A) and (B) at the desired temperature in the required time in the presence of all other ingredients of the inventive composition. The exact necessary amount of said catalyst component will depend upon the particular catalyst.

### i) Photoactivatable Catalyst (C1)

Catalyst capable of being photo-activatable is preferably selected among organometallic compounds, i.e., a metallic compound comprising carbon-containing ligands, or salts thereof. In a preferred embodiment photoactive catalyst (C1) has metal carbon bonds, including sigma- and pi-bonds. Preferably the catalyst capable of being photo-activated (C1) is an organometallic complex compound having at least one metal carbon sigma bond, still more preferably a platinum complex compound having preferably one or more sigma-bonded alkyl and/or aryl group, preferably alkyl group(s). Sigma-bonded ligands include in particular, sigma-bonded organic groups, preferably sigma-bonded C1-C6-alkyl, more preferably sigma-bonded methyl groups, sigma-bonded aryl groups, like phenyl, Si and O substituted sigma bonded alkyl or aryl groups, such as trisorganosilylalkyl groups, sigma-bonded silyl groups, like trialkyl silyl groups. Most preferred photo-activatable catalysts include η⁵-(optionally substituted)-cyclopentadienyl platinum complex compounds having sigma-bonded ligands, preferably sigma-bonded alkyl ligands.

Further catalysts capable of being photoactivated include (i-diolefin)-(sigma-aryl)-platinum complexes (see e.g. U.S. Pat. No. 4,530,879).

Examples of catalysts capable of being photo-activated include η-diolefin-α-aryl-platinum complexes, such as disclosed in U.S. Pat. No. 4,530,879, EP 122008, EP 146307 (corresponding to U.S. Pat. No. 4,510,094 and the prior art documents cited therein), or US 2003/0199603, and also platinum compounds whose reactivity can be controlled by way for example using azodicarboxylic esters, as disclosed in U.S. Pat. No. 4,640,939 or diketonates.

Platinum compounds capable of being photo-activated that can be used are moreover those selected from the group having ligands selected from diketones, e.g. benzoylacetones or acetylenedicarboxylic esters, and platinum catalysts embedded into photo-degradable organic resins. Other Pt-catalysts are mentioned by way of example in U.S. Pat. No. 3,715,334 or U.S. Pat. No. 3,419,593, EP 1 672 031 A1 and Lewis, Colborn, Grade, Bryant, Sumpter, and Scott in Organometallics, 1995, 14, 2202-2213, all incorporated by reference here.

Catalysts capable of being photo-activated can also be formed in-situ in the silicone composition to be shaped, by using Pt(0)-olefin complexes and adding appropriate photo-activatable ligands thereto.

The catalysts capable of being photo-activated that can be used here are, however, not restricted to these above-mentioned examples.

In one embodiment of the current invention the photo-activatable or irradiation-activatable catalyst (C1) is selected from organometallic platinum compounds, preferably from optionally substituted cyclopentadienyl platinum compounds, preferably from (η⁵-cyclopentadienyl)-trimethyl-platinum and (η⁵-cyclopentadienyl)-triphenyl-platinum complexes, most preferably component (C1) is (methylcyclopentadienyl)-trimethyl platinum(IV).

The catalyst capable of being photoactivated (C1) can be used as such or supported on a carrier.

The catalyst (C1) is used in a concentration of 0.1 to 3.5 weight percent based on the total weight of whole silicone composition.

The most preferred catalyst (C1) is selected from (η⁵-cyclopentadienyl)-trimethyl-platinum and (η⁵-cyclopentadienyl)-triphenyl-platinum complexes, most preferred component (C1) is (methylcyclopentadienyl)-trimethyl platinum(IV).

Photoactivated curing is effected with light of a wavelength in the range of 200 to 500 nm (UV light). In the process according to the present invention an UV radiation source for the light activation is chosen, for example, from the group of UV lamps such as xenon lamps which can be operated as flash lamps, undoped mercury lamps or mercury lamps doped with iron or gallium, black light lamps and excimer lamps as well as LED UV lamps. The total amount of exposure at a wavelength of 365 nm is preferably in a range from 100 mJ/cm² to 10 J/cm². The wavelength used to cure the curable silicone composition of the current invention is not narrowly limited as long as the wavelength is capable to cure the composition within a reasonable timescale. According to the present invention the silicone composition is curable upon photoactivation for a period of 0.01 to 300 sec.

### ii) Non Photoactivatable Catalyst (C2)

The non-photoactivatable catalyst (C2) is different from the photo-activatable catalyst (C1). The non-photoactivatable catalyst (C2) generally does not contain sigma or pi bonds and no ligands selected from the groups of diketones, e.g., benzoylacetones or acetylenedicarboxylic esters. The non-photoactivatable catalyst (C2) is used to cure the silicone composition according to the invention in the shadow areas of the mold containing for example connectors receiving the potting composition. These shadow areas are areas that radiation or UV light cannot reach. In these shadow areas generally only the curing with the non-photoactivatable catalyst (C2) is possible.

A platinum catalyst is preferred for the catalyst (C2). Examples of platinum catalysts include platinum fine powder, platinum black, platinum-supported silica fine powder, platinum-supported activated carbon, chloroplatinic acid, alcohol solutions of chloroplatinic acid, olefin complexes of platinum, and alkenylsiloxane complexes of platinum. Alkenylsiloxane complexes of platinum are especially preferred. Examples of alkenylsiloxanes include 1,3-divinyl-1,1,3,3-tetramethyldisiloxane, 1,3,5,7-tetramethyl-1,3,5,7-tetravinylcyclotetrasiloxane, alkenyl siloxanes in which some of the methyl groups in the alkenyl siloxane have been substituted with ethyl groups or phenyl groups, and alkenyl siloxanes in which some of the vinyl groups in the alkenyl siloxane have been substituted with allyl groups or hexenyl groups. Because the stability of platinum-alkenylsiloxane complexes is good, 1,3-divinyl-1,1,3,3-tetramethyldisiloxane is especially preferred. Because the stability of platinum-alkenylsiloxane complexes can be improved, these complexes preferably include organosiloxane oligomers, for example, alkenyl siloxanes and dimethyl siloxane oligomers such as 1,3-divinyl-1,1,3,3-tetramethyldisiloxane, 1,3-diallyl-1,1,3,3-tetramethyldisiloxane, 1,3-divinyl-1,3-dimethyl-1,3-diphenyldisiloxane, 1,3-divinyl-1,1,3,3-tetraphenyldisiloxane, and 1,3,5,7-tetramethyl-1,3,5,7-tetravinylcyclotetrasiloxane. The addition of alkenyl siloxanes is especially preferred.

The catalyst in component (C2) exhibits activity without exposure to radiation or photocuring. However, it preferably also exhibits activity at relatively low temperatures. More specifically, these catalysts exhibit activity in compositions in a range from 20° C. to 200° C. and promote a hydrosilylation reaction, preferably (C2) is used in the range from 20° C. to 80° C. The amount of component (C2) depends on the type of catalyst and the type of composition, but the amount of metal atoms in the catalyst is usually in a range from 0.01 to 50 ppm and preferably in a range from 0.1 to 30 ppm relative to the mass of the composition.

The most preferred catalyst (C2) is selected from platinum complexes with 1,3-divinyl-1,1,3,3-tetramethyldisiloxane, platinum complexes with 1,3-diallyl-1,1,3,3-tetramethyldisiloxane, platinum complexes with 1,3-divinyl-1,3-dimethyl-1,3-diphenyldisiloxane, platinum complexes with 1,3-divinyl-1,1,3,3-tetraphenyldisiloxane, and platinum complexes with 1,3,5,7-tetramethyl-1,3,5,7-tetravinylcyclotetrasiloxane, even more preferred catalyst (C2) is a platinum complex with 1,3,5,7-tetramethyl-1,3,5,7-tetravinylcyclotetrasiloxane.

Non-photoactivated curing is effected by using a temperature range of 20 to 80° C. for a period of 0.5 to 2 hours to allow the curing of the silicone composition in the areas not accessible to photoactivatable curing or UV light.

In another embodiment, the silicone composition used comprises auxiliary additives (D) described as follows.

### Component (D)

Optionally the=curable silicone composition according to the current invention comprises one or more auxiliary components (component (D)). In one embodiment of the current invention the used curable silicone composition comprises less than 3 weight-% of (D) preferably less than 1 weight-% of (D), more preferably 0 to 0.1 weight-% of an (D) based on the total weight of the curable silicone composition.

In one embodiment, component (D) is preferably selected from at least one of
(D1): at least one organosiloxane, comprising at least one alkoxy silyl group,
(D2): at least one organosilane, comprising at least one alkoxy silyl group,
(D3):at least one aromatic organic compound having at least two aromatic moieties and at least one group reactive in hydrosilylation.

Component (D1) is preferably a polyorganosiloxane comprising at least one unit selected from the group consisting of
R(H)SiO_{2/2} and
R⁵(R)SiO_{2/2},
wherein R is as defined above and may be identical or different, R⁵ is selected from the group consisting of unsaturated aliphatic group with up to 14 carbon atoms, epoxy-group-containing aliphatic group with up to 14 carbon atoms, cyanurate-containing group, and an isocyanurate-containing group, and
further comprising at least one unit of the formula (3):

—O_{2/2}(R)Si—R⁴—SiR_{d}(OR³)_{3-d} (3)

wherein
R is as defined above and may be identical or different,
R³ is selected from H (hydrogen) and alkyl radicals having 1 to 6 carbon atoms, and may be identical or different,
R⁴ is a difunctional optionally substituted hydrocarbyl radical with up to 15 carbon atoms, which may contain one or more heteroatoms selected from O, N and S atoms, and which is bond to the silicon atoms via an Si—C-bond, and
d is 0 to 2.

Examples of component (D1) include compounds of the formulas (3a- 3d):

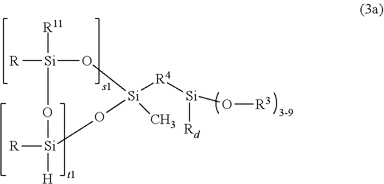

R¹¹ is R or R⁵, wherein R, R³, R⁴ and R⁵ are as defined above and may be identical or different,
s1=0-6, preferably 1
t1=0-6, preferably 1 or 2
s1+t1=2-6, preferably 2 or 3
with the proviso that there is at least one group —(OSi(R)H)— or —(OSi(R)(R¹¹)— in the compound. In one embodiment, the component (D1) is selected from a compound of the formula:

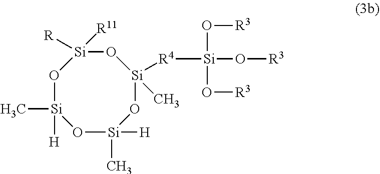

wherein R, R³, R⁴ and R¹¹ are as defined before, and ring positions isomers thereof, and a compound of the formula:

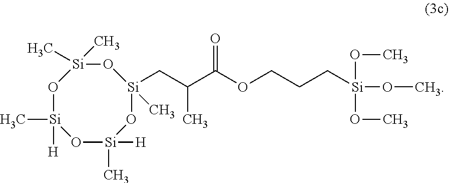 [SMILES: CO[Si](CCCOC(=O)C(C)C[Si]1(C)O[SiH](C)O[SiH](C)O[Si](C)(C)O1)(OC)OC]

In one embodiment, the component (D1) is selected from a compound of formula:

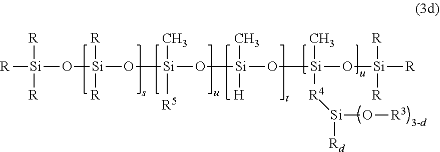

wherein:
R, R³, R⁴, R⁵ are as defined above,
s=0-10 preferably =0-5
t=0-50 preferably =2-30
u=1-10 preferably =1
s+t+u=<70
with the proviso that there is at least one group —(OSi(R)H)— or —(OSi(R)(R⁵)— in the compound. These compounds may comprise to a certain content Q or T branching groups, replacing the D units.

R⁵ is for example selected from:

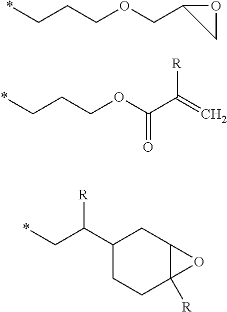

Component (D2) is preferably selected from compounds of the formula (4):

X—(CR⁶₂)ₑ—Y—(CH₂)ₑSiR_{d}(OR³)_{3-d}

wherein
X is selected from the group consisting of halogen, pseudohalogen, unsaturated aliphatic group with up to 14 carbon atoms, epoxy-group-containing aliphatic group with up to 14 carbon atoms, cyanurate-containing group, and an isocyanurate-containing group,
Y is selected from the group consisting of a single bond, a heteroatomic group selected from —COO—, —O—, —S—, —CONH—, —HN—CO—NH—,
R⁶ is selected from hydrogen and R as defined above,
e is 0, 1, 2, 3, 4, 5, 6, 7, or 8, and may be identical or different,
R is as defined above and may be identical or different,
R³ is as defined above and may be identical or different,
d is 0, 1, or 2.

Preferred examples of component (D2) include:

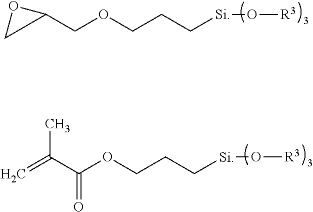

(3e) for upper structure and (3f) for lower structure

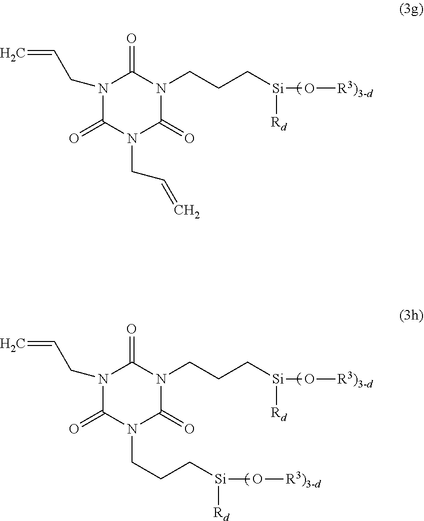

wherein R and d are as defined above.

Component (D2) can serve as in-situ surface treating agent for filler (E). It is preferred to use mixtures of silanes of the component (D2)

Component (D3) is preferably selected from compounds of the formula (3i):

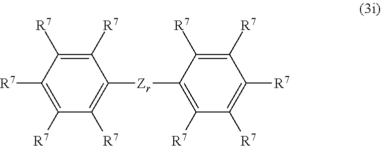

wherein
r is 0 or 1,
R⁷ may be the same or different group, which is selected from the group consisting of a hydrogen atom, a hydroxyl group, a halogen atom, an alkyl group, alkenyl group, alkoxy group, alkenyloxy group, alkenylcarbonyloxy group and an aryl group, and
a group of formula -E_{f}-Si(OR)_{3-d}R_{d}, wherein R is identical or different, and d is as defined above,
a group of formula —O—Si(R)₂R₁, wherein R and R₁ are as defined above,
a group of formula -E_{f}-Si(R)₂H, wherein R is as defined above,
wherein E is a divalent organic group with up to 8 carbon atoms and 0 to 3 hetero atomic groups selected from —O—, —NH—, C═O, and —C(═O)O—, and
f is 0 or 1,
and Z is selected from the following groups:

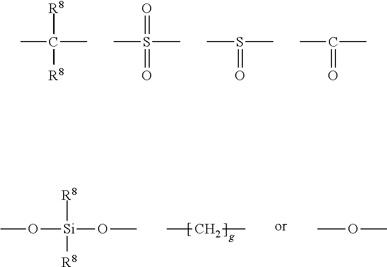

wherein R⁸ is selected from the group of a hydrogen atom, a halogen atom, or a substituted or unsubstituted alkyl group, aryl group, alkenyl group and alkynyl group, and
g is a positive number of at least 2,
wherein at least one of the groups selected from R⁷ and R⁸ is reactive in hydrosilylation.

Preferred components (D3) include:

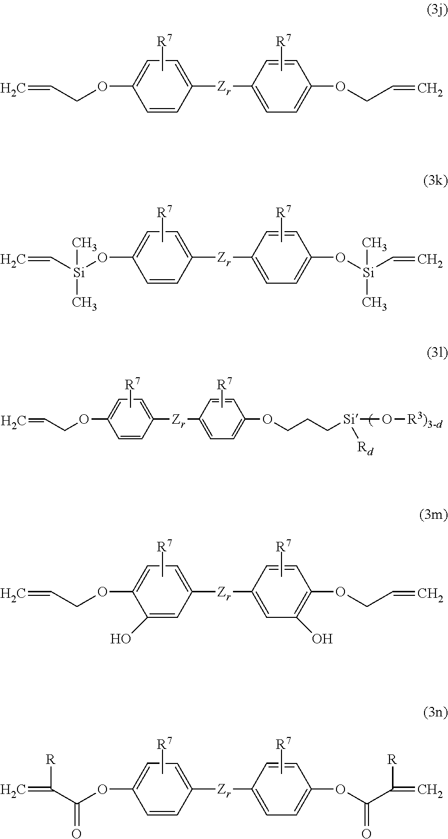

wherein Z, r, R⁷, R³, R and d are each as defined above.”

In some embodiments, components (D1), (D2), and (D3) can be present in an amount of from about 0.1 weight percent to about 10 weight percent; from about 0.5 weight percent to about 7 weight percent; or from about 1 weight percent to about 5 weight percent based on the total weight of the composition. In one embodiment, the composition comprises at least one component (D1) in an amount of from about 0.1 weight percent to about 10 weight percent; from about 0.5 weight percent to about 7 weight percent; or from about 1 weight percent to about 5 weight percent based on the total weight of the composition.

Other auxiliary components (component (D)) include:
Fillers: Examples of suitable fillers include those selected from, for example, TiO₂, nano-TiO₂, optical lightener (like Tinopal OB) and nano-silica.

Silicon dioxide nanoparticles are also known as silica nanoparticles or nano-silica, which have stability, low toxicity and an ability to be functionalized with a range of molecules and polymers.

Nano-silica particles are divided into P-type and S-type according to their structure. The P-type particles are characterized by numerous nanopores, which have a pore rate of 0.61 m1/g and exhibit a higher ultraviolet reflectivity compared to the S-type; the latter also has a comparatively smaller surface area. When the filler is nano-silica and is included into the silicone composition according to the invention, then the cured silicone composition will be transparent for a good UV curing.

In one embodiment, the curable silicone composition does not contain any reinforcing filler in particular silica.

### Non Reinforcement Filler:

Examples of materials serving as fillers or extenders (BET-surface areas<50 m²/g) are known as non-reinforcing fillers. They include for example powdered quartz, diatomaceous earths, powdered crystoballites, micas, aluminum oxides, and aluminum hydroxides. Titanium dioxides or iron oxides, Zn oxides, chalks, or carbon blacks whose BET surface areas are from 0.2 to less than 50 m²/g can be used also as heat stabilizer. These fillers are available under variety of trade names, examples being Sicron®, Min-U-Sil®, Dicalite®, Crystallite®. The materials known as inert fillers or extenders with BET surface areas below 50 m2/g should advantageously comprise no particles (<0.005% by weight) above 100 μm for use in silicone rubbers, in order that further processing generates no problems during downstream processing, e.g., passage through sieves or nozzles, or the mechanical properties of the articles produced therefrom are adversely affected.

In one embodiment according to the invention, the used silicone composition comprises a UV tracer compound as compound (D) such as a benzoxazole compound and/or a bis-benzoxazole compound and/or a thiophenediyl benzoxazole compound and/or thiophenediyl bis-benzoxazole compound. Preferably the UV tracer compound is the 2,5-thiophenediylbis(5-tert-butyl-1,3-benzoxazole), also found as MPI Bright 100 UV Tracer from MPI Chemie, where it is used under UV light as marker for voids or uneven coverage or uneven curing in the mold for electronic components. The UV tracer a compound will fluoresce when exposed to UV electromagnetic radiation.

### Hydrosilylation Inhibitor Compound

The rate of the hydrosilylation reaction can be affected as known by a number of additional compounds, the so-called inhibitors used as compound (D). This allows to further influence the rate of crosslinking after photoactivation, that is, the temperature and the time can be determined at which/in which the silicone rubber composition or mixture is cured or vulcanized to an elastomeric molded body after photoactivation. Appropriate inhibitors for the photoactivatable hydrosilylation of the present invention with platinum are inhibitors such as vinyl siloxanes, 1,3-divinyltetramethyldisiloxane or tetravinyltetramethyltetracyclosiloxane. Other known inhibitors such as ethynylcyclohexanol, 3-methylbutynol or dimethyl maleate can be used too. The inhibitors are used to delay the curing reaction after photoactivation in a desired manner. Basically, any inhibitors known for the class of the group of platinum metals can be used, if not already a sufficiently long processing time is achieved by selection of the ligands of the catalyst (C2). An exemplary embodiment is to use the catalysts with the vinyl siloxane based inhibitor even more preferably with tetravinyltetramethyltetracyclosiloxane. The total amount of the possible inhibitor auxiliaries as component (D) is preferably 0 to 15 parts by weight based on 100 parts by weight of component (A) and (B).

### Opacifying Fillers

Among the opacifying fillers are also in particular non-transparent, in particular inorganic, pigments or carbon black.

The use of these opacifying fillers is preferred only when pigmentation is necessary or the physical function like thermal or electrical conductivity is a requirement.

The use of opaque non-transparent fillers requires changing the usual sequence of the activation and shaping steps in the process. Normally, if no or transparent fillers are used, the photo-activation through irradiation is carried out after the final shaping process. If opaque non-transparent fillers, which would inhibit the photo-activation of the photo-activatable catalyst, are used, the photo-activation step is carried out before the opaque non-transparent fillers are incorporated and the mixture is shaped.

### Component (E): Adhesion Enhancing Agent:

In another embodiments the silicone composition comprises an adhesion enhancing agent (E) wherein the adhesion enhancing agent is a metal based compound, like titanate compounds more preferably tetra-n butyltitanate which allows the silicone composition to better adhere to metal surfaces, preferably Aluminum and also to plastic substrates such as, but not limited to, PBT (Polybutylenterephthalate), PPS (Polybutylensuccinate), ABS(Acrylnitril-Butadien-Styrol-Copolymer), PC (polycarbonate), PPO (polypropylene oxide), PP (polypropylene), HDPE (High-Density Polyethylen), and the like, more preferably PBT.

In a further embodiment, the silicone composition comprises an adhesion enhancing agent (E) in an amount of 0.001 part to 0.1 part per weight related to 100 parts per weight of (A), preferably from 0.005 to 0.075 per weight related to 100 parts per weight of (A), more preferably from 0.01 to 0.06 per weight related to 100 parts per weight of (A), even more preferably from 0.015 to 0.05 per weight related to 100 parts per weight of (A).

In one embodiment, the composition is provided as a composition comprising (a) a first part comprising the (A) component, the (C1) photo-activatable catalyst, and the (C2) non-photo-activatable catalyst; and (b) a second part comprising the (B) component. The second part (b) may optionally include one or more additional components such as one or more alkenyl functional polyorganosiloxanes (A), adhesion enhancing agents, inhibitors etc.

Ratios between different components in the used silicone composition

In one embodiment according to the invention the silicone composition for potting application for electronic components comprises:
100 parts per weight of at least one polyorganosiloxane (A) having at least one, preferably at least two alkenyl groups bonded to a silicon atom,
0.1 to 30 parts per weight of at least one organohydrogensiloxane (B) having at least one SiH group,
0.1 to 3.5 weight percent of at least one photo-activatable hydrosilylation catalyst (C1) based on total weight of (A) and (B),
1 to 1000 ppm at least one non-photo-activatable hydrosilylation catalyst (C2) based on the total weight of the components (A) and (B), and
0 to 10 parts of optionally additives (D).

In one embodiment, the composition includes an additive (E) selected from an adhesion enhancing agent in an amount of 0.1 to 10 parts per weight related to 100 parts per weight of component (A). In one embodiment, the adhesion enhancing agent is selected from a titanate compound.

In another embodiment according to the invention the silicone composition for potting application comprises:
100 parts per weight of at least one linear poly organosiloxane (A) having one alkenyl group bonded to a silicon atom at each end,
0.01 to 30 parts by weight of component (B) selected from the group of (B1) a linear SiH-containing polyorganosiloxane and (B2) a branched SiH-containing polyorganosiloxane,
0.1 to 3.5 weight percent of at least one photo-activatable hydrosilylation catalyst (C1) based on total weight of (A) and (B),
1 to 1000 ppm at least one non-photo-activatable hydrosilylation catalyst (C2) based on the total weight of the components (A) and (B), and
0 to 10 parts of optionally additives (D).

In one embodiment, the composition includes an adhesion enhancing agent in an amount of 0.1 to 10 parts per weight related to 100 parts per weight of component (A). In one embodiment, the adhesion enhancing agent is selected from a titanate compound.

In one embodiment according to the invention the used silicone composition for potting application comprises:
100 parts per weight of at least one linear poly organosiloxane (A) having one alkenyl, preferably at least two alkenyl groups bonded to a silicon atom at each end,
0.01 to 30 parts by weight of component (B) selected from the group of (B1) a linear SiH-containing polyorganosiloxane having one SiH group at each end and (B2) a branched SiH-containing polyorganosiloxane consisting of at least one M^{H} unit and at least one Q unit,
0.1 to 3.5 weight percent of at least one photo-activatable hydrosilylation catalyst (C1) based on total weight of (A) and (B),
1 to 1000 ppm at least one non-photo-activatable hydrosilylation catalyst (C2) based on the total weight of the components (A) and (B), and
0 to 10 parts of optionally additives (D).

In one embodiment, the composition includes an additive (E) selected from an adhesion enhancing agent in an amount of 0.1 to 10 parts per weight related to 100 parts per weight of component (A). In one embodiment, the adhesion enhancing agent is selected from a titanate compound.

In one embodiment according to the invention the used silicone composition for potting application comprises:
100 parts per weight of at least one linear polyorganosiloxane (A) having one alkenyl, preferably at least two alkenyl groups bonded to a silicon atom at each end,
0.01 to 30 parts by weight of component (B) selected from the group of (B1) a linear SiH-containing polyorganosiloxane having one SiH group at each end and (B2) a branched SiH-containing polyorganosiloxane consisting of at least one M^{H} unit and at least one Q unit,
0.1 to 3.5 weight percent of at least one photo-activatable hydrosilylation catalyst (C1) based on total weight of (A) and (B),
1 to 1000 ppm at least one non-photo-activatable hydrosilylation catalyst (C2) based on the total weight of the components (A) and (B), and
0 to 10 parts of optionally additives (D).
0 to 10 parts of an adhesion enhancing agent (F) selected from titanate compounds.

In one embodiment, the above silicone composition has a viscosity below 10000 mPa·s, preferably below 8000 mPa·s, more preferably below 5000 mPa·s at 20° C. and D=10 s⁻¹ according to DIN 53019.

In another embodiment, the above silicone composition has a viscosity below 1000 mPa·s, preferably below 800 mPa·s, more preferably below 500 mPa·s at 20° C. according to DIN 53015.

In another embodiment according to the invention, the curable silicone composition which comprises:
100 parts per weight of at least one linear polydiorganosiloxane (A) having one alkenyl group bonded to a silicon atom at each end of the formula

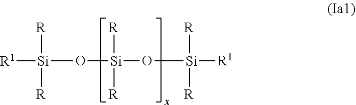

wherein each R is independently selected from saturated organic groups, preferably methyl, each R¹ is independently selected from alkenyl groups, preferably vinyl groups, and x is ≥0.
0.01 to 30 parts by weight of component (B) selected from the group of (B1) a linear SiH-containing polydiorganosiloxane having one SiH group at each end of formula

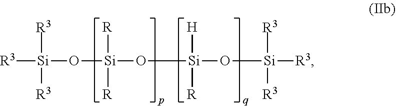

wherein R is independently selected from saturated organic groups, and one R³ is H and remaining R³ groups are R groups independently selected from saturated organic groups and p≥0 and q=0 and (B2) a branched SiH-containing polyorganosiloxane consisting of M^{H} units and Q units,
0.1 to 3.5 weight percent of at least one photo-activatable hydrosilylation catalyst (C1) (alkyl-cyclopentadienyl) Pt (alkyl)₃, preferably the alkyl group is methyl based on total weight of (A) and (B),
1 to 1000 ppm at least one non-photo-activatable hydrosilylation catalyst (C2) selected from the group of hexachloloroplatinic and alkenylsiloxane complexes of platinum based on the total weight of the components (A) and (B), and
optionally 0.1 to 10 parts of (D1) to (D3), preferably (D1) of formula (3c).
0.1 to 10 parts of adhesion enhancing agent (E) based on titanate compounds.
optionally 0 to 10 parts of compound (D) as UV tracer selected from the group of benzoxazole compound and/or a bis-benzoxazole compound and/or a thiophenediyl benzoxazole compound and/or thiophenediyl bis-benzoxazole compound.

In another embodiment, the above silicone composition has a viscosity below 1000 mPa·s, preferably below 800 mPa·s, more preferably below 500 mPa·s at 20° C. measured according to DIN 53015. This silicone composition exhibits adhesion to the surface of the chamber/cavity/mold of the electronic component.

In still another embodiment, the curable silicone composition is provided as a kit of 2 components system (part A and part B mixed as a 1 to 1 weight ratio) as the potting application requires flowing of the curable silicone composition and a quick curing before the next steps of the process (turning upside down of the electronic component etc). Excellent mechanical properties are obtained for this kind of curable silicone composition.

The present compositions can be employed as potting and encapsulation materials suitable for protecting electrical and electronic components from environmental stresses and other stresses. The curable silicone composition of the current invention is used, for example, as material for potting on integrated circuits in a chamber/cavity/mold in electronic devices as a potting compound in potting and encapsulation of electronic components in automotive, power applications for the protection against moisture, dust and environmental hazards.

Potting is the process of filling a complete mechanical or electronic assembly with a liquid material that is subsequently cured with moisture, UV light, and/or thermal energy. Typically, the potting material is dispensed into a plastic housing (chamber), pocket (cavity), or case (mold) where the electronic unit is placed. In potting applications, the silicone composition flows over and around a component or fills in a chamber/cavity/mold to protect components therein. Examples include heavy duty electrical cords and connectors, electronics in plastic cases, circuit boards and concrete repair. Encapsulation includes building a frame or dam around an objection, e.g., wires, passive components, etc., and filling the space with a liquid material between the frame and the object and subsequently curing the material with moisture, UV light, and/or thermal energy.

In one embodiment according to the invention, a process of curing the curable silicone composition to a cured silicone composition in a chamber/cavity/mold having areas not readily accessible to direct UV light irradiation, comprises the steps:
a) applying the said curable silicone composition to the chamber/cavity/mold in a manner so as to cover both the light accessible and the areas not readily accessible to direct UV light,
b) irradiating the substrate with UV irradiation sufficient to substantially cure the composition in the areas directly accessible to UV light, and
c) exposing the composition on the substrate to a temperature of >20° C. for sufficient time to cure the composition in the areas not accessible to UV light.

The areas not accessible to UV light are also named here shadow areas. A cured product is obtained by exposing the curable silicone composition according to the invention to irradiation, preferably to UV light to perform hydrosilylation reaction and in parallel a non-photoactivatable hydrosilylation reaction.

In one embodiment according to the invention, the process of curing of the curable silicone compositions to a cured silicone composition for the manufacture of connector potting, the process comprising the steps:
a. applying said curable silicone composition to a chamber/cavity/mold with connectors,
b. exposing said curable silicone composition to UV light
c. then curing in areas not accessible to UV light in a temperature range of 20 to 80° C.

In one embodiment according to the invention, the process of curing of the curable silicone compositions to a cured silicone composition for the manufacture of connector potting, the process comprising the steps:
a. applying said curable silicone composition to a chamber/cavity/mold with connectors,
b. exposing said curable silicone composition to UV light for less than five minutes, preferably less than one minute,
c. then curing in areas not accessible to UV light in a temperature range of 20 to 80° C.

In another embodiment, the invention related to an article prepared by the steps comprising:
I. mixing, so as to form a curable composition as described above
II. applying a potting of/dispensing said curable composition to a chamber/cavity/mold; and
III. curing said curable composition to said chamber/cavity/mold by exposing said silicone composition in the potting containing chamber/cavity/mold to a source of UV radiation and thereafter to a non-photoactivatable curing.

In a preferred embodiment of the process according to the present invention the silicone composition is curable upon photoactivation for a period of 0.01 to 300 sec. Photoactivation is carried out with light of a wavelength in the range of 200 to 450 nm (UV light). In the process according to the present invention an UV radiation source for the light activation is chosen, for example, from the group of UV lamps such as xenon lamps which can be operated as flash lamps, undoped mercury lamps or mercury lamps doped with iron or gallium, black light lamps and excimer lamps as well as LED UV lamps. The total amount of exposure at a wavelength of 365 nm is preferably in a range from 100 mJ/cm² to 10 J/cm². The wavelength used to cure the curable silicone composition of the current invention is not narrowly limited as long as the wavelength is capable to cure the composition within a reasonable timescale. The photoactivation curing is followed by a non-photoactivated curing in a temperature range of 20 to 80° C. for a period of 0.5 to 2 hours to allow the curing of the silicone composition in the areas not accessible to UV light.

The use of a two component addition curable system (kit of a part A and part B) allows a quicker curing with some time to dispense the composition in the mold which is convenient for the potting application.

In one embodiment, the invention provides a process of curing the curable composition by the process comprising accelerating the curing in the temperature range from 20 to 80° C.

In one embodiment, the invention also provides a cured composition prepared by the process of curing the inventive curable silicone composition with a UV intensity of 0.5 J/cm² to 20 MJ/cm² followed by curing in the temperature range of 20 to 80° C.

In one embodiment the cured composition has a hardness in penetration range 20 to 80 10/mm tested with 1/4 cone according to DIN 51579 and in another embodiment the hardness is in Shore 00 range of 0 to 70 according to ASTM D2240-2015.

The electronic components that the present compositions may be employed to protect are not particularly limited. Electronic components may include, for example, any type of PCB (printed circuit board) assemblies as well as switches and electronic connectors with pins. Typically, the electronic assemblies consist of passive or active components which are driven by current or voltage.

Potting materials according to the invention are used to protect entire or sometimes just certain areas of the circuit board assemblies for engine and/or transmission control units, electronic power steering units, power supplies or transformers and chassis and safety related electronic control units (e.g. ABS, ESP, etc).

The other applications are related to electronic connectors. A connector typically consists of a plastic housing (engineered plastic such as PBT, PPS, ABS etc) and metal connector pins. Connector potting applications are prevalent in many applications, ranging from automotive, telecommunication, military, aerospace, and consumer-electronics.

Power electronics and power modules applications. In particular potting and encapsulation of IGBT (Insulated Gate Bipolar Transistor) modules. IGBT modules have been developed to be used as switching elements for the power converters of variable-speed drives for motors, uninterruptable power supplies, and others. An IGBT is a semiconductor device that combines the high-speed switching performance of a power MOSFET ( ) with the high-voltage/high-current handling capabilities of a bipolar transistor. The main function of our silicone material according to the invention in this IGBT application is to provide electrical insulation of the wires and high voltage areas in the module to prevent arcing or a short circuit.

Typically connector pins are mounted in/through the plastic housing of the connector. As the pins are reaching through the plastic housing and as there is a small gap due to production tolerances between the metal connector pin and the plastic housing, proposed silicone composition as potting material acts a barrier to prevent water ingress.

The potting material is dispensed into the connector, filling the cavity by flowing into the gaps. After filling and flowing, the material is cured with exposure to UV light. As there are areas below the connector pins which might not get exposed to UV light; “so called shadow areas” a second cure mechanism without UV is required.

In addition, the silicone composition as cured material according to the invention will provide one or more of the following: (a) long term stability over a broad temperature range, (b) retention of flexibility, adhesion, and/or sealing even in extreme conditions, (c) permanent flexibility and low cure shrinkage for stress relief, (d) low stress and non-cracking, (e) ability to withstand exposure to vibration, impact and shock, (f) exceptional durability (g) excellent thermal shock resistance, (h) exceptional moisture protection, (i) minimal expansion and contraction with temperature changes, (j) excellent electrical insulation properties for use with sensitive circuits, (k) low volatile solutions, (l) customizable cure rates allowing the material to match the assembly process, and/or (m) wide range of viscosities—from semi-flowable to flowable liquids.

What has been described above includes examples of the present specification. It is, of course, not possible to describe every conceivable combination of components or methodologies for purposes of describing the present specification, but one of ordinary skill in the art may recognize that many further combinations and permutations of the present specification are possible. Accordingly, the present specification is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

The foregoing description identifies various, non-limiting embodiments of a silicone composition, processes for curing such compositions, and the use of such compositions in various applications. Modifications may occur to those skilled in the art and to those who may make and use the invention. The disclosed embodiments are merely for illustrative purposes and not intended to limit the scope of the invention or the subject matter set forth in the claims.

### EXAMPLES

### Example 1 & Example 2

Silicone compositions were obtained by mixing part A and B (as displayed in Table 1 below, for Example 1 and Example 2) at a weight ratio 1:1 for each corresponding example. The two silicone compositions (of Example 1 and Example 2) differ by the absence (Example 2) or the presence (Example 1)) of the UV tracer MPI Bright 100.

The UV tracer is used for leaks detection or seal defects detection. The UV tracer is added after the blending of part A with part B.

The work life at 23° C. corresponds to the time to get the doubling of the initial viscosity of the final silicone rubber composition (A+B) of corresponding example.

The silicone composition mixture of the Example is then irradiated first by a metal halide Lamp with a UV intensity for green strength of 4.5.

TABLE 1
Compositions of the invention for preparing samples as in Example 1 and 2

| | Ex 1 | Ex 1 | Ex 2 | Ex 2 |
|---|---|---|---|---|
| Composition | part A | part B | part A | part B |
| Vinyl terminated polydimethylsiloxane (A) Viscosity | | 62.63 | | 62.65 |
| 350 mPa · s at 20° C. and DIN 53015 | | | | |
| Vinyl terminated polydimethylsiloxane (A) Viscosity | 25 | | 25 | |
| 100 mPa · s at 20° C. and DIN 53015 | | | | |
| Vinyl terminated polydimethylsiloxane (A) Viscosity | 74.935 | 10 | 74.934 | 10 |
| 250 mPa · s at 20° C. DIN 50315 | | | | |
| Branched Polyhydrogenmethylsiloxane M₂^{H}Q where M^{H} is | | 0.46 | | 0.45 |
| (CH₃)₃SiO_{1/2}— (B2) having 8.5-10.4 mmol SiH/g | | | | |
| Hydride terminated polydimethylsiloxane (B1) viscosity 14 | | 26 | | 26 |
| mPa · s at 20° C. and DIN 50315 | | | | |
| Catalyst (C2) H₂PtCl₆ in polymer A) of viscosity of | 0.003 | | 0.003 | |
| 0.2 Pa · s containing 1.47 wt-% Pt | | | | |
| D₃^{H}D—CH₂—CH(CH₃)—C(═O)—O—(CH₂)₃—Si(OCH₃)₃ | | 0.9 | | 0.9 |
| (D1) of formula (3c) wherein D units have methyl groups | | | | |
| Catalyst (C1) trimethyl(methylcyclopentadienyl) | 0.011 | | 0.011 | |
| platinum(IV) (Me—CpPt(Me)₃) | | | | |
| Tetra-n butyltitanate (E) | 0.05 | | 0.05 | |
| ViD₄ inhibitor (D) | 0.001 | | 0.002 | |
| MPI Bright 100 UV Tracer (D) | | 0.012 | | |
| 2,5-thiophenediylbis(5-tert-butyl-1,3-benzoxazole) | | | | |

Silicone composition of each of the examples (Example 1 and Example 2) was cured in two ways as follows:
45 sec with a UV radiation of 100 mW/cm²(UV Curing 4.5 J/cm²)
Non photocurable curing at 23° C. for the shadow areas.

(The LW curing is also possible with UV LED at 365 nm with a UV intensity for green strength of 24-9 s with a UV radiation of 500 nW/cm2 corresponding to 4.5 J/cm²)

TABLE 2
Attributes of uncured and cured samples of the compositions
(Example 1 and Example 2) of the invention

| | Ex 2 Part A/ | Ex 1 Part A/ |
|---|---|---|
| Uncured Properties (23° C.) | Part B | Part B |
| Appearance | Clear/Clear | Clear/Clear |
| Viscosity [mPa · s] at 20° C. | 230/210 | 230/210 |
| DIN 53015 | | |
| Viscosity [mPa · s] after Mixing | 230 | |
| part A and part B at 20° C. | | |
| DIN 53015 | | |
| Mixing weight ratio part A and | 1:1 | |
| part B for each Example | | |
| Work life at 23° C. [min] ¹⁾ | 15 | |
| UV intensity for green strength | 4.5 | |
| [J · cm²] For Metal halide lamp | | |
| UV tracer MPI 100 (additive D)) | No | Yes |

| | |
|---|---|
| Cured properties | 45 sec 100 mW/cm² + 16 h |
| | at 23° C. |
| Lap shear adhesion glass/glass [MPa] | 0.7 |
| Lap shear adhesion glass/PBT [MPa] | 0.2 |
| Volume resistivity [(Ω/mm] | 1 × 10¹³ |
| Dielectric Strength [kV/cm] | 20 |
| Impurities Na⁺ K⁺ Cl⁻ [ppm] | <2 |

¹⁾ Time to double viscosity

The Lap shear of the cured silicone compositions according to the invention was measured on different substrate combinations for Ex 1 and Ex 2.
Substrate combination: glass/other substrate
Bond line thickness between the 2 substrates: 100 μm
Dual cure conditions: UV radiation 45 s 100 mW/cm² plus 16 hours at 23° C. (non photo-activatable curing)

TABLE 3
Lap shear strength and cohesive failure of the compositions
(Example 1 and Example 2) of the invention

| Substrate combination | Lap shear strength | % cohesive |
|---|---|---|
| Glass/substrate below | [MPa] | failure |
| Aluminum AI 5754 (AlMg3) | 0.16 | 80 |
| PBT-GF30FR | 0.32 | 90 |
| Ultradur B4300 G6 HR from | | |
| BASF | | |
| PBT-GF30 | 0.10 | 60 |
| Ultradur B4315 G6 HR from | | |
| BASF | | |

Lap shear (DIN Norm EN 1465) was used to measure the strength of the adhesive properties under shear strength. (see https://leitfaden.klebstoffe.com/en/6-5-1-leap-shear-test/)

The substrate combination glass/used silicone composition according to the invention/PBT-GF30FR Ultradur B4300 G6 HR has the highest value for lap shear and the highest percentage of cohesive failure indicating that the adhesive is very suitable for this substrate combination.

Ageing tests at 85° C./85% relative humidity (r.h.) were performed to see the effect on the lap shear adhesion of the silicone composition of Ex 1 or Ex 2

For the testing, following conditions were used:
Substrate combination used: glass/PBT (GF30 Ultradur B4315 G6 HR from BASF)
Bond line thickness: 100 μm
Curing conditions: UV radiation 45 s 100 mW/cm² and parallel non photo-activatable addition curing at 23° C.

TABLE 4
Lap shear strength upon ageing, of the composition
(Example 1) of the invention

| Ageing time at | |
|---|---|
| 85° C./85% (r · h) | Lap shear strength [MPa] |
| Initial | 0.10 |
| 250 h | 0.13 |
| 500 h | 0.12 |
| 1000 h | 0.14 |

The silicone adhesive of Ex 1 or 2 shows 40% variation in the Lap shear strength after ageing at 85° C./85% relative humidity (r.h.), which is suitable for the potting application.

The hardness buildup was measured for the inventive Ex 1 with 2 different UV sources.

TABLE 5a
Hardness buildup after UV curing of inventive example Ex 1 with
UV source being the hand-held lamp (housing holding the metal
halide tube, reflector, safety thermostat, cooling fan, frame
with blue filter) UV-H 255 Panacol 100 mW/cm²

| Time after | Hardness | Hardness | Hardness |
|---|---|---|---|
| first UV | measured after | measured after | measured after |
| irradiation [min] | 30 s irradiation | 45 s irradiation | 60 s irradiation |
| 2 | — | 28 | 28 |
| 3 | 27 | 31 | 34 |
| 5 | 34 | 33 | 34 |
| 6 | 35 | 35 | 35 |
| 10 | 37 | 37 | 37 |
| 15 | 37 | 38 | 38 |
| 30 | 40 | 40 | 40 |
| 60 | 40 | 40 | 40 |
| 150 | 43 | 43 | 43 |
| 1 d | 46 | 46 | 46 |

TABLE 5b
Hardness buildup after UV curing of Ex 1 with UV source being
Hönle LED Spot 100 HP K 365 nm (1000 mW/cm²).

| Time after | Hardness | Hardness | Hardness |
|---|---|---|---|
| first UV | measured after | measured after | measured after |
| irradiation [min] | 1 s irradiation | 8 s irradiation | 16 s irradiation |
| 4 | — | 28 | 28 |
| 5 | — | 31 | 34 |
| 6 | — | 35 | 35 |
| 10 | 2 | 37 | 37 |
| 15 | 28 | 38 | 38 |
| 30 | 40 | 40 | 40 |
| 60 | 40 | 40 | 40 |
| 1 d | 46 | 46 | 46 |

The above compositions are suitable for potting application because
they are easily pourable and filling of small cavities due to their low viscosity (about 220 mPa·s at 20° C. according to DIN 53015).
they ensure after curing tightness against outside media.

### Examples 3 and 4

The silicone composition mixture of Example 3 or 4 (the composition of which is displayed in table 5 below) was irradiated first by a metal halide Lamp with a U V intensity for green strength of 4.5 and cured as follows:
45 see with a UV radiation of 100 mW/cm²(UV Curing 4.5 J/cm²)

Alternatively, UV LED at 365 nm with a UV intensity for green strength of 24 for 9 s and a UV radiation of 500 mW/cm²) is used

TABLE 5
Attributes of the composition (Example 3 and Example 4) of the invention

| | Ex 3 (parts per | Ex 4 (parts per |
|---|---|---|
| Composition | weight) | weight) |
| Vinyl terminated polydimethylsiloxane (A) Viscosity | 89.6955 | 89.67 |
| 350 mPa · s at 20° C. and D = 10 s⁻¹ | | |
| Branched Polyhydrogenmethylsiloxane M₂^{H}Q as component | 0.2 | 0.2 |
| (B2) having 8.5-10.4 mmol SiH/g | | |
| Hydride terminated polydimethylsiloxane viscosity 14 | 9.65 | 9.65 |
| mPa · s at 20° C. and D = 10 s⁻¹ (B1) | | |
| Catalyst (C2) H₂PtCl₆ in polymer (A) of viscosity of | 0.002 | 0.002 |
| 0.2 Pa · s having 1.47 wt % Pt | | |
| D₃^{H}D—CH₂—CH(CH₃)—C(═O)—O—(CH₂)₃—Si(OCH₃)₃ | 0.45 | 0.45 |
| (D1) of formula (3c) wherein D units have methyl groups | | |
| Catalyst (C1) trimethyl(methylcyclopentadienyl) | 0.003 | 0.003 |
| platinum(IV) (Me—CpPt(Me)₃) | | |
| Tetra-n butyltitanate (E) | — | 0.03 |
| Hardness Shore 00 | 40 | 40 |
| Adhesion on aluminum 5754 | 0.14 | 0.16 |
| % cohesive failure | 0 | 70 |
| Adhesion on PBT-GF30FR Ultradur B4300 G6 HR | 0.16 | 0.26 |
| % cohesive failure | 0 | 100 |

The cohesive failure is measured using OverLapShear (OLS) Test and Failure Modes with an Instron device on a cured sample using a test substrate size 25 mm×10 cm, a bond area 25 mm×25 mm×1 mm and crosshead pull speed 10 mm/min. 100% cohesive failure means the silicone adhesive has broken in itself due to very good adhesion to substrate.

As shown in Table 5, Ex 3 does not contain the tetra-n butyltitanate (E) and after irradiation by UV there is a big difference in the percentage of cohesion of failure for two different substrates like Aluminum 5754 or on PBT-GF30FR Ultradur B4300 G6 HR. These experiments display that in the presence of tetra-n butyltitanate there is a surprising increase of adhesion of the composition on substrates such as aluminum and PBT. The percentage of cohesion failure is 100% for Ex 4 indicating a surprisingly strong adhesion between the substrate (either Aluminium or PBT) and the silicone composition of Ex.4. The composition of the invention provides complete curing-by UV and shadow curing in addition to surprisingly enhancing adhesion on low energy substrates such as A1 and PBT. Such enhancement in adhesion is presumably accelerated by a co-operative involvement of the metal (titanate) compound along with the UV-activated curing catalyst, which is hitherto unknown. The curing observed for the examples 3 and 4 was of the same quality with the same value of hardness i.e., 40 shore 00.

### Example 5: Use of a Two Components Inventive Silicone Composition of Example 1 in a Connector Assembly

Automotive electrical connectors are specifically designed for use in automobile electrical systems.

Automobile systems have undergone massive transformation and today modem systems are extensively wired and controlled by a microprocessor. This has increased the demand for high-quality and reliable wiring and electrical connectors.

Typically connector pins are mounted in/through the plastic housing of the connector. As the pins are reaching through the plastic housing and as there is a small gap due to production tolerances, between the metal connector pin and the plastic housing, our silicone material acts a barrier to prevent water ingress.

The potting material as a two part inventive silicone composition of Example 1 (part A and part B were mixed at a weight ratio of 1:1) is dispensed into the connector, filling the cavity by flowing into the gaps. After filling and flowing, the inventive silicone composition of Example 1 was cured with exposure to UV light as indicated in Table 1. As there are areas below the connector pins which were not get exposed to UV light; “so called shadow areas” a second cure mechanism without UV was required. The non-photoactivatable catalyst was acting for curing at room temperature and after 1 hour the cured silicone composition had a hardness shore 00 of 40 very close to the final hardness. The connector was then further processed.

1. A potting compound for use in the potting of electronic equipment, the potting compound comprising a curable silicone composition the composition comprising:
(A) at least one polyorganosiloxane having at least one alkenyl groups bonded to a silicon atom,
(B) at least one organohydrogensiloxane having at least one SiH group,
(C1) at least one photo-activatable hydrosilylation catalyst,
(C2) at least one non-photo-activatable hydrosilylation catalyst, and
(D) optionally additives.

2. The potting compound according to claim 1, wherein the electronic components are for automotive or power applications.

3. The potting compound according to claim 1 for the protection of an electronic equipment against moisture, dust and environmental hazards.

4. The potting compound according to any of claim 1, wherein the at least one polyorganosiloxane having at least one alkenyl group A) is selected from the groups of polyorganosiloxanes having the formula (Ia):
[MₐD_{b}T_{c}Q_{d}R⁹ₑ]ₘ (Ia)
wherein the indices in formula (Ia) are defined as follows:
a=0-10
b=0-2000
c=0-50
d=0-1
e=0-300
m=1-1000
with a, b, c, d and m being such that the viscosity of component (A) at 20° C. is less than 15000 mPa·s(measured at a shear rate of D=10 s⁻¹ according to DIN 53019 and for viscosities below 5000 mPa·s measured according to DIN 53015),
and
M is selected from R₃SiO_{1/2} and M*,
D is selected from R₂SiO_{2/2} and D*,
T is selected from RSiO_{3/2} and T*, and
Q=SiO_{4/2},
R⁹ is selected from divalent organic groups bound via carbon to two silicon atoms, and wherein each R, which may be the same or different, is selected from an optionally substituted alkyl group with up to 30 carbon atoms, an optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation, and
wherein M*=R¹ₚR₃₋ₚSiO_{1/2}, D*=R¹_{q}R_{2-q}SiO_{2/2}, T*=R¹SiO₃/2,
wherein
p=1-3
q=1-2
R is as defined before, and
R¹ is selected from alkenyl groups.

5. The potting compound according to any of claim 1, wherein the component (A) has the formula (Ia1) 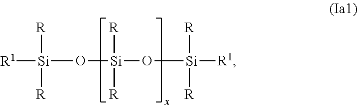
wherein R¹ and R are as defined above and x is ≥0.

6. The potting compound according to claim 1, wherein the component (B) is selected from the group of (B1) a linear SiH-containing polyorganosiloxane and (B2) a branched SiH-containing polyorganosiloxane.

7. The potting compound according to claim 1, wherein the component (B) is selected from the group of (B1) a linear polydiorganosiloxane having an SiH group at each end, and (B2) a branched SiH-containing polyorganosiloxane containing at least one M^{H} unit.

8. The potting compound according to claim 1, wherein the branched SiH-containing polyorganosiloxane (B2) are selected from polyorganosiloxanes comprising at least one siloxy unit selected from the group consisting of a Q unit: 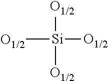
and a T unit: 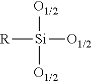
wherein R is as defined above, and at least one siloxy unit M^{H}: 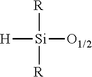
wherein R is alkyl.

9. The potting compound according to claim 1, wherein the branched SiH-containing polyorganosiloxane B2) are selected from polyorganosiloxanes consisting of at least one siloxy unit Q: 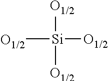
and at least one siloxy unit M^{H}: 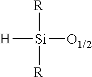
wherein R is as defined above.

10. The potting compound according to claim 1, wherein the SiH-containing polyorganosiloxane resins (B2) are selected from polyorganohydrogensiloxanes consisting of Q and M^{H} units of the formula
{[Q][M^{H}]_{0.01-10}}ₘ
wherein Q and M^{H} are as defined above, and m is about 1 to about 20.

11. The potting compound according to claim 1 comprising a linear polydiorganosiloxane (B1) having an SiH group at each end, and a branched SiH-containing polyorganosiloxane (B2) consisting of Q and M^{H} units of the formula
{[Q][M^{H}]_{0.01-10}}ₘ
wherein Q, M^{H} and m are as defined above.

12. The potting compound according to claim 1, wherein the organo-metallic hydrosilylation catalyst (C1) or (C2) is selected from the group consisting of transition metal complex catalysts selected from platinum, palladium, rhodium, nickel, iridium, ruthenium, and iron complexes and combinations thereof.

13. The potting compound according to claim 1, wherein (C1) is a photo-activatable platinum catalyst selected from the group consisting of η⁵-(optionally substituted) cyclopentadienyl platinum(IV) complexes, β-diketonato trimethylplatinum (IV) complexes, bis(β-diketonato) platinum(JI) complexes, bis(phosphine) platinum(II) complexes, cyclooctadiene platinum(II) complexes, and mixtures thereof.

14. The potting compound according to claim 1, wherein the non-photoactivatable hydrosilylation catalyst (C2) is platinum catalyst selected from the group consisting of platinum compounds such as chloroplatinic acid, or platinum complexes such as platinum/vinylsiloxane complexes, or mixtures thereof.

15. The potting compound according to claim 1, further comprising the additive (D) selected from of the group consisting of a hydrosilylation reaction inhibitor.

16. The potting compound according to claim 1, further comprising as additives (D) at least one selected from the group consisting of an optical brightener or UV tracer (fluorescent whitening agent).

17. The potting compound according to claim 1, comprising:
100 parts per weight of at least one polyorganosiloxane (A) having at least one alkenyl group bonded to a silicon atom,
0.1 to 30 parts per weight of at least one organohydrogensiloxane (B) having at least one SiH group,
0.1 to 3.5 weight percent of at least one photo-activatable hydrosilylation catalyst (C1) based on total weight of (A) and (B),
1 to 1000 ppm at least one non-photo-activatable hydrosilylation catalyst (C2) based on the total weight of the components (A) and (B), and
0.1 to 10 parts of optionally additives (D).

18. The potting compound according to claim 1, comprising:
100 parts per weight of at least one polyorganosiloxane (A) having at least one, alkenyl group bonded to a silicon atom,
0.1 to 25 parts per weight of at least one linear polyorganosiloxane (B1) having an SiH group at each end,
0.1 to 5 parts per weight of at least one polyorganohydrogensiloxane (B2) having at least one siloxy unit Q and at least one siloxy unit M^{H} as defined above,
1 to 1000 ppm of at least one photo-activatable hydrosilylation catalyst (C1) based on total weight of (A) and (B),
0.1 to 3.1 weight percent at least one non-photo-activatable hydrosilylation catalyst (C2) based on the total weight of the components (A) and (B), and
0.1 to 10 parts (D) optionally additives.

19. The potting compound according to claim 17 of 18, wherein the said silicone composition has a viscosity below 1000 mPa·s at 20° C. measured according to DIN 53015.

20. The potting compound of claim 1 wherein:
(A) is selected from at least one linear polyorganosiloxane having at both ends one alkenyl group bonded to a silicon atom,
(B) is selected from a linear polydiorganosiloxane (B1) having an SiH group at each end, and an SiH-containing polyorganosiloxane resin (B2) consisting of Q and M^{H} units as defined above,
(C1) at least one photo-activatable hydrosilylation catalyst,
(C2) at least one non-photo-activatable hydrosilylation catalyst, and

21. The potting compound according to claim 1, further comprising at least one adhesion enhancing agent (E).

22. The potting compound of claim 21, wherein the adhesion agent is selected from a titanate compound.

23. The potting compound according to claim 22 wherein the adhesion enhancing agent (E) is tetra-n butyltitanate.

24. The potting compound according to claim 23 wherein the said silicone composition has a viscosity below 1000 mPa·s at 20° C. measured according to DIN 53015.

25. A process of curing the curable silicone composition as defined in claim 1 to a cured silicone composition in a chamber/cavity of the electronic component having areas not readily accessible to direct UV light irradiation, the process comprising:
a) applying the said curable silicone composition into the chamber/cavity in a manner so as to fill in the chamber/cavity.
b) irradiating the chamber/cavity with UV irradiation sufficient to substantially cure the composition in the areas directly accessible to UV light, and
c) exposing the composition on the chamber/cavity to a temperature of ≥20° C. for sufficient time to cure the composition in the areas not accessible to UV light.

26. A process of curing of the curable silicone compositions as defined in claim 1 to a cured silicone composition for the manufacture of connector potting, the process comprising
a) applying said curable silicone composition to a chamber/cavity/pocket comprising pin connectors,
b) exposing said curable silicone composition to UV light, and
c) then curing in areas not accessible to UV light in a temperature range of 20 to 80° C.

27. A cured composition obtained by the curing of the curable silicone composition according to claim 25 by a UV radiation cure step followed by a cure step at a temperature in the range of ≥20° C. and ≤80° C.

28. An article prepared by the steps, comprising:
I. mixing, so as to form a curable composition as defined in claim 21,
II. applying a potting of/dispensing said curable composition into a chamber/cavity of the electronic component; and
III. curing said curable composition to said chamber/cavity by exposing the said curable composition in the potting chamber/cavity to a source of UV radiation and thereafter non photoactivatable curing said curable composition at a temperature in the range of 20 to 80° C.

29. The article of claim 28 wherein the substrate is a circuit board or pin connector.

30. The curable silicone composition, as defined in claim 1 in the form of a kit of two parts system.

31. A composition comprising:
(a) a first part comprising (A) at least one polyorganosiloxane having at least one alkenyl group bonded to a silicon atom, (C1) at least one photo-activatable hydrosilylation catalyst, and (C2) at least one non-photo-activatable hydrosilylation catalyst, and
(b) a second part comprising (B) at least one organohydrogensiloxane having at least one SiH group, and (D1) a polyorganosiloxane, different from (B)comprising at least one unit selected from the group consisting of
R(H)SiO_{2/2} and
R⁵(R)SiO_{2/2},
wherein R is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation, R is selected from the group consisting of unsaturated aliphatic group with up to 14 carbon atoms, epoxy-group-containing aliphatic group with up to 14 carbon atoms, cyanurate-containing group, and an isocyanurate-containing group, and
further comprising at least one unit of the formula (3):
—O_{2/2}(R)Si—R⁴—SiR_{d}(OR³)_{3-d} (3)
wherein
R in formula (3) may be identical or different and is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation,
R³ is selected from H (hydrogen) and alkyl radicals having 1 to 6 carbon atoms, and may be identical or different,
R⁴ is a difunctional optionally substituted hydrocarbyl radical with up to 15 carbon atoms, which may contain one or more heteroatoms selected from O, N and S atoms, and which is bond to the silicon atoms via an Si—C-bond, and
d is 0 to 2.

32. The composition of claim 31, wherein the polyorganosiloxane (A) is selected from at least one linear polyorganosiloxane having at least one alkenyl group; and the organohydrogensiloxane (B) is selected from at least one linear polydiorganosiloxane (B1) having an SiH group at each end, and at least one SiH-containing polyorganosiloxane resin (B2) consisting of Q and M^{H} units where Q is Si_{4/2}, and M^{H} is HR₂SiO_{1/2}, where R of the M^{H} unit may be identical or different and is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4) alkyleneoxy groups, the groups R being free of aliphatic unsaturation.

33. The composition of claim 32 comprising:
100 parts per weight of the at least one polyorganosiloxane (A) having at least one alkenyl group bonded to a silicon atom,
0.1 to 25 parts per weight of the at least one linear polyorganosiloxane (B1) having an SiH group at each end,
0.1 to 5 parts per weight of the at least one polyorganohydrogensiloxane (B2) having at least one siloxy unit Q and at least one siloxy unit M^{H} as defined above,
1 to 1000 ppm of the at least one photo-activatable hydrosilylation catalyst (C1) based on total weight of (A) and (B),
0.1 to 3.1 weight percent at least one non-photo-activatable hydrosilylation catalyst (C2) based on the total weight of the components (A) and (B),
0.1 to 10 weight percent of the component (D1) based on the total weight of part (a) and (b), and
0.001 to 10 parts per weight of an additive.

34. The composition of claim 31, wherein (D1) is selected from a compound of the formula (3a): 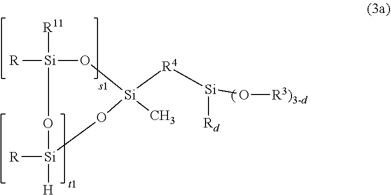
R¹¹ is R or R⁵; and R⁴ is a difunctional optionally substituted hydrocarbyl radical with up to 15 carbon atoms, which may contain one or more heteroatoms selected from O, N and S atoms, and which is bond to the silicon atoms via an Si—C-bond,
s1=0-6
t1=0-6
s1+t1=2-6
with the proviso that there is at least one group —(OSi(R)H)— or —(OSi(R)(R¹¹)— in the compound.

35. The composition of claim 34, wherein the compound of formula (3a) has the formula:

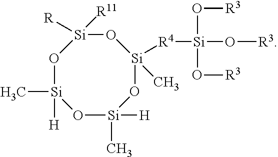

36. The composition of claim 34, wherein the compound of formula (3a) has the formula:

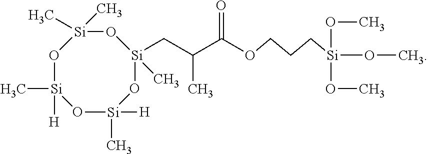 [SMILES: CO[Si](CCCOC(=O)C(C)C[Si]1(C)O[SiH](C)O[SiH](C)O[Si](C)(C)O1)(OC)OC]

37. The composition of claim 31, wherein the polyorganosiloxane (A) is of the formula (Ia1): 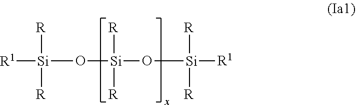
wherein each R is independently selected from a saturated organic group, each R¹ is independently selected from an alkenyl group, and x is ≥0.

38. The composition of claim 31, wherein the composition, upon combining parts (a) and (b), has a viscosity of from about 50 mPa·s to about 10 Pa·s at 20° C. measured at a shear rate of D=10 s⁻¹ according to DIN 53019 for viscosities above 5000 mPa·s and measured according to DIN 53015 at 20° C. for viscosities below 5000 mPa·s.

39. The composition of claim 31, wherein the composition, upon combining parts (a) and (b), has a viscosity of 100 mPa·s to about 1000 mPa·s at 20° C. measured according to DIN 53015.

40. The composition of claim 31, wherein the composition, upon combining parts (a) and (b), has a viscosity of 200 mPa·s to about 800 mPa·s at 20° C. measured according to DIN 53015.

41. The composition of claim 31, wherein the composition, upon combining parts (a) and (b), has a viscosity of 300 mPa·s to about 500 mPa·s at 20° C. measured according to DIN 53015.

42. The composition according to claim 31, wherein the silicone composition has a viscosity below 1000 mPa·s at 20° C. measured according to DIN 53015.

43. A process of curing the curable silicone composition as defined in claim 31 in a chamber/cavity of an electronic component having areas not readily accessible to direct UV light irradiation, the process comprising:
(i) combining part (a) and part (b) to form the curable silicone composition;
(ii) applying the curable silicone composition into the chamber/cavity in a manner so as to fill in the chamber/cavity;
(iii) irradiating the chamber/cavity with UV irradiation sufficient to substantially cure the composition in the areas directly accessible to UV light; and
(iv) exposing the composition on the chamber/cavity to a temperature of ≥20° C. for sufficient time to cure the composition in the areas not accessible to UV light.

44. A process of curing the curable silicone compositions as defined in claim 31 to a cured silicone composition for the manufacture of connector potting or encapsulation of electronic components, the process comprising
(i) combining part (a) and part (b) to form the curable composition;
(ii) applying said curable silicone composition to a chamber/cavity/pocket comprising pin connectors,
(iii) exposing said curable silicone composition to UV light, and
(iv) curing in areas not accessible to UV light in a temperature range of 20 to 80° C.

45. An article prepared by the steps, comprising:
(i) mixing part (a) and part (b), so as to form a curable composition as defined in claim 31,
(ii) applying a potting of/dispensing of said curable composition into a chamber/cavity of the electronic component; and
(iii) curing said curable composition to said chamber/cavity by exposing the said curable composition in potting chamber/cavity to a source of UV radiation and thereafter non-photoactivatable curing said curable composition at a temperature in the range of 20 to 80° C.

46. The article of claim 45, wherein the substrate is a circuit board or a connector plug.

47. A composition comprising:
(A) at least one polyorganosiloxane having at least one, alkenyl groups bonded to a silicon atom,
(B) at least one organohydrogensiloxane having at least one SiH group,
(C1) at least one photo-activatable hydrosilylation catalyst,
(C2) at least one non-photo-activatable hydrosilylation catalyst, and
(D1) A polyorganosiloxane comprising at least one unit selected from the group consisting of
R(H)SiO_{2/2} and
R⁵(R)SiO_{2/2},
wherein R is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation, R is selected from the group consisting of unsaturated aliphatic group with up to 14 carbon atoms, epoxy-group-containing aliphatic group with up to 14 carbon atoms, cyanurate-containing group, and an isocyanurate-containing group, and
further comprising at least one unit of the formula (3):
—O_{2/2}(R)Si—R⁴—SiR_{d}(OR³)_{3-d} (3)
wherein
R in formula (3) may be identical or different and is selected from optionally substituted alkyl with up to 30 carbon atoms, optionally substituted aryl with up to 30 carbon atoms, and an organic group bound to Si via carbon comprising a poly(C2-4)-alkyleneoxy moiety with up to 1000 (C2-C4)alkyleneoxy groups, the groups R being free of aliphatic unsaturation,
R³ is selected from H (hydrogen) and alkyl radicals having 1 to 6 carbon atoms, and may be identical or different,
R⁴ is a difunctional optionally substituted hydrocarbyl radical with up to 15 carbon atoms, which may contain one or more heteroatoms selected from O, N and S atoms, and which is bond to the silicon atoms via an Si—C-bond, and
d is 0 to 2.

48. A composition according to claim 47 further comprising an adhesion enhancing agent (E).

49. The composition of claim 48 having a lap shear strength of at least 0.1 MPa when interposed between a first substrate that is glass and a second substrate that is either Aluminium or PBT.

50. The composition of claim 48 having cohesive failure in the range of 60-100% in the cured state on a metal or plastic substrate in a OverLapShear (OLS) Test

51. A composition according to claim 50 having cohesive failure in the range of 60-100% in the cured state on an aluminium or PBT substrate in a OverLapShear (OLS) Test

52. Use of a curable silicone composition of claim 1 as a potting compound in the potting of electronic components.

53. The use according to claim 52, wherein the electronic components are for automotive or power applications.

54. The use according to claim 52, wherein the electronic components are for automotive or power applications.

55. The use of according to claim 52 for the protection against moisture, dust, and/or environmental hazards.
